(19) United States
(12) Patent Application Publication
(10) Pub. No.: US 2023/0039770 A1
(43) Pub. Date: Feb. 9, 2023

(54) IMAGING ELEMENT, MANUFACTURING METHOD, AND ELECTRONIC APPARATUS

(71) Applicant: SONY SEMICONDUCTOR SOLUTIONS CORPORATION, KANAGAWA (JP)

(72) Inventor: JUNPEI YAMAMOTO, KANAGAWA (JP)

(21) Appl. No.: 17/758,200

(22) PCT Filed: Dec. 25, 2020
(86) PCT No.: PCT/JP2020/048728

§ 371 Date: Jun. 29, 2022

(30) Foreign Application Priority Data
Jan. 10, 2020 (JP) 2020-002710

(51) Int. Cl. H01L 27/30; H01L 27/28

(52) U.S. Cl. CPC H01L 27/307; H01L 27/286

(57) ABSTRACT

The present technology relates to an imaging element, a manufacturing method, and an electronic apparatus capable of forming a photoelectric conversion part in a steep impurity profile. Laminated first and second photoelectric conversion parts are provided between a first surface of a semiconductor substrate and a second surface opposite to the first surface, an impurity profile of the first photoelectric conversion part is a profile having a peak on the first surface side, and an impurity profile of the second photoelectric conversion part is a profile having a peak on the second surface side. A side on which an impurity concentration of the first photoelectric conversion part is low and a side on which an impurity concentration of the second photoelectric conversion part is low face each other. The present technology can be applied to, for example, an imaging element in which a plurality of photoelectric conversion parts are laminated in a semiconductor substrate.

### TECHNICAL FIELD

The present technology relates to an imaging element, a manufacturing method, and an electronic apparatus, for example, an imaging element having a steep profile, a manufacturing method, and an electronic apparatus.

### BACKGROUND ART

In a conventional general CCD image sensor or CMOS image sensor, a configuration in which green, red, and blue pixels are arranged on a plane and green, red or blue photoelectric conversion signal is obtained from each pixel is adopted. A method of arranging the green, red, and blue pixels includes, for example, a Bayer arrangement in which sets each having two green pixels, one red pixel and one blue pixel are arranged.

The Bayer arrangement has loss of sensitivity because green light and blue light do not pass through a color filter and are not used for photoelectric conversion in red pixels. In addition, false colors may be generated because color signals are generated by performing interpolation processing between pixels. Further, the CCD image sensor and the CMOS image sensor are miniaturized. Due to miniaturization of an image sensor, a pixel size may be reduced, the number of photons incident on a unit pixel may be reduced, the sensitivity may decrease, and S/N may be reduced.

As a method for solving these problems, an image sensor is known in which three photoelectric conversion layers are laminated in the vertical direction to obtain photoelectric conversion signals of three colors in one pixel. As such a structure in which photoelectric conversion layers of three colors are laminated in one pixel, for example, a sensor which includes a photoelectric conversion unit that detects green light and generates signal charge corresponding to the green light, provided above a silicon substrate, and detects blue light and red light through two photodiodes (PDs) laminated inside the silicon substrate has been proposed (refer to PTL 1 and 2, for example).

Due to an absorption coefficient difference, the PDs laminated inside the silicon substrate photoelectrically convert blue light near a light receiving surface and red light in the layer below the light receiving surface. When an image sensor having such a structure is manufactured, a method of forming a PD for blue light configured having a PN junction first, depositing silicon to a predetermined thickness through epitaxial growth, and then forming a PD for red light, for example, when the back surface is a light receiving surface has been proposed (refer to PTL 3).

### CITATION LIST

### Patent Literature

[PTL 1]
JP 2003-332551 A
[PTL 2]
JP 2005-340571 A
[PTL 3]
JP 2011-138927 A

### SUMMARY

### Technical Problem

In the conventional manufacturing method for manufacturing an image sensor having a structure in which photoelectric conversion layers of three colors are laminated in one pixel, for example, after forming a PD for blue light, high-temperature epitaxial growth is performed. Accordingly, there is a possibility that P-type and N-type impurities forming the PD for blue light may diffuse and thus there was a possibility that a steep impurity profile of blue light could not be formed. Therefore, there is a possibility that a saturation signal amount of blue light cannot be sufficiently secured, particularly in fine pixels.

In addition, in the case of manufacturing without epitaxial growth, it is necessary to inject impurities into deep positions with high energy, and thus it is difficult to form a steep impurity profile.

The present technology has been made in view of such a situation, and makes it possible to form a steep profile.

### Solution to Problem

An imaging element of one aspect of the present technology includes laminated first and second photoelectric conversion parts provided between a first surface of a semiconductor substrate and a second surface opposite to the first surface, wherein an impurity profile of the first photoelectric conversion part is a profile having a peak on the first surface side, and an impurity profile of the second photoelectric conversion part is a profile having a peak on the second surface side.

A manufacturing method of one aspect of the present technology is a manufacturing method of a manufacturing apparatus for manufacturing an imaging element, the manufacturing method including manufacturing an imaging element including laminated first and second photoelectric conversion parts provided between a first surface of a semiconductor substrate and a second surface opposite to the first surface, wherein an impurity profile of the first photoelectric conversion part is a profile having a peak on the first surface side, and an impurity profile of the second photoelectric conversion part is a profile having a peak on the second surface side.

An electronic apparatus of one aspect of the present technology includes: an imaging element including laminated first and second photoelectric conversion parts provided between a first surface of a semiconductor substrate and a second surface opposite to the first surface, wherein an impurity profile of the first photoelectric conversion part is a profile having a peak on the first surface side, and an impurity profile of the second photoelectric conversion part is a profile having a peak on the second surface side; and a processing unit that processes a signal from the imaging element.

In the imaging element of one aspect of the present technology, the laminated first and second photoelectric conversion parts are provided between the first surface of the semiconductor substrate and the second surface opposite to the first surface, the impurity profile of the first photoelectric conversion part is a profile having a peak on the first surface side, and the impurity profile of the second photoelectric conversion part is a profile having a peak on the second surface side.

In the manufacturing method of one aspect of the present technology, the imaging element is manufactured.

In the electronic apparatus of one aspect of the present technology, the imaging element is included, and a signal from the imaging element is processed.

The electronic apparatus may be an independent device or an internal block constituting a single device.

### BRIEF DESCRIPTION OF DRAWINGS

FIG. 1 is a diagram showing a schematic configuration of an imaging element to which the present technology is applied.

FIG. 2 is a plan view showing the configuration of the imaging element.

FIG. 3 is a diagram showing a cross-sectional configuration example according to an embodiment of the imaging element.

FIG. 4 is a diagram for describing a method of manufacturing the imaging element.

FIG. 5 is a diagram for describing the method of manufacturing the imaging element.

FIG. 6 is a diagram for describing the method of manufacturing the imaging element.

FIG. 7 is a diagram for describing an impurity profile of a photodiode.

FIG. 8 is a diagram for describing the impurity profile of the photodiode.

FIG. 9 is a diagram for describing a conventional method for manufacturing an imaging element.

FIG. 10 is a diagram for describing another method of manufacturing the imaging element.

FIG. 11 is a diagram showing another cross-sectional configuration example of the imaging element.

FIG. 12 is a diagram for describing another method of manufacturing the imaging element.

FIG. 13 is a diagram for describing another method of manufacturing the imaging element.

FIG. 14 is a diagram for describing another method of manufacturing the imaging element.

FIG. 15 is a diagram for describing the impurity profile of the photodiode.

FIG. 16 is a diagram showing another cross-sectional configuration example of the imaging element.

FIG. 17 is a diagram showing a configuration of an example of an electronic apparatus.

FIG. 18 is a diagram showing an example of a schematic configuration of an endoscopic operation system.

FIG. 19 is a block diagram showing an example of a functional configuration of a camera head and a CCU.

FIG. 20 is a block diagram showing an example of a schematic configuration of a vehicle control system.

FIG. 21 is an explanatory diagram showing an example of installation positions of a vehicle exterior information detection unit and an imaging unit.

### DESCRIPTION OF EMBODIMENTS

Hereinafter, forms for implementing the present technology (hereinafter referred to as embodiments) will be described.

### <Overall Configuration of Imaging Device>

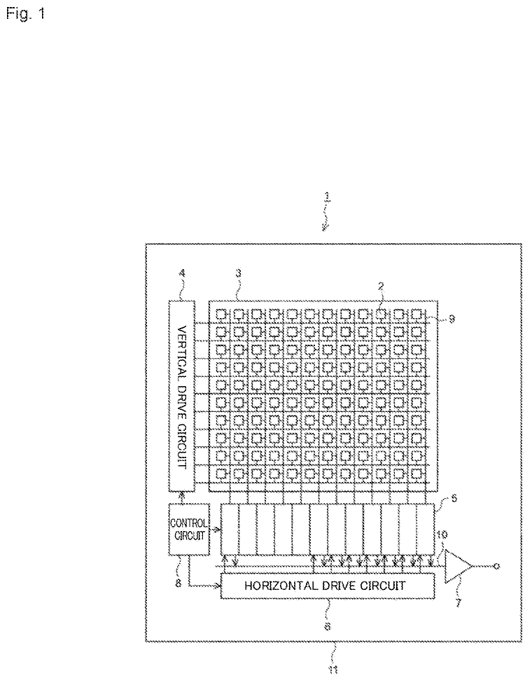

FIG. 1 is a schematic configuration diagram showing an entire imaging element 1 according to a first embodiment. The imaging element 1 in FIG. 1 is a back-illuminated CMOS imaging device.

The imaging element 1 of FIG. 1 includes a pixel area 3 including a plurality of pixels 2 arranged on a substrate 11 made of silicon, a vertical drive circuit 4, a column signal processing circuit 5, a horizontal drive circuit 6, an output circuit 7, a control circuit 8, and the like.

The pixels 2 each composed of a photodiode that is a photoelectric conversion element and a plurality of pixel transistor are regularly arranged in a two-dimensional array form on the substrate 11. The pixel transistors constituting each pixel 2 may be four pixel transistors including a transfer transistor, a reset transistor, a select transistor, and an amplification transistor or may be three transistors excluding the select transistor.

The pixel area 3 includes a plurality of pixels 2 that are regularly arranged in a two-dimensional array form. The pixel area 3 includes an effective pixel area (not shown) in which light is actually received, and signal charge generated by photoelectric conversion is amplified and read out to the column signal processing circuit 5, and a black reference pixel area (not shown) for outputting optical black that serves as a reference for a black level. The black reference pixel area is generally formed on the outer periphery of the effective pixel area.

The control circuit 8 generates a clock signal, a control signal, and the like as a reference for operations of the vertical drive circuit 4, the column signal processing circuit 5, the horizontal drive circuit 6, and the like on the basis of a vertical synchronization signal, a horizontal synchronization signal, and a master clock signal. Then, the clock signal, the control signal and the like generated by the control circuit 8 are input to the vertical drive circuit 4, the column signal processing circuit 5, the horizontal drive circuit 6, and the like.

The vertical drive circuit 4 is composed of, for example, shift registers, and sequentially selects and scans each pixel 2 of the pixel area 3 in units of rows in the vertical direction. Therefore, the pixel signal based on the signal charge generated in the photodiode of each pixel 2 according to the intensity of the light received is supplied to the column signal processing circuit 5 through a vertical signal line 9.

One of column signal processing circuits 5 is disposed for example, for each column of the pixels 2, and the signal output from the pixels 2 for one row is subjected to signal processing such as noise removal and signal amplification using the signal from the black reference pixel area (not shown, but formed around the effective pixel region) for each pixel column. A horizontal selection switch (not shown) is provided between the output end of the column signal processing circuit 5 and a horizontal signal line 10.

The horizontal drive circuit 6 is composed of, for example, shift registers, and sequentially outputs a horizontal scanning pulse and thus selects each of the column signal processing circuits 5 in order, and outputs a pixel signal from each of the column signal processing circuits 5 to the horizontal signal line 10.

The output circuit 7 performs signal processing on the signal sequentially supplied from each of the column signal processing circuits 5 through the horizontal signal line 10 and outputs it.

### <Planar Configuration of Pixel>

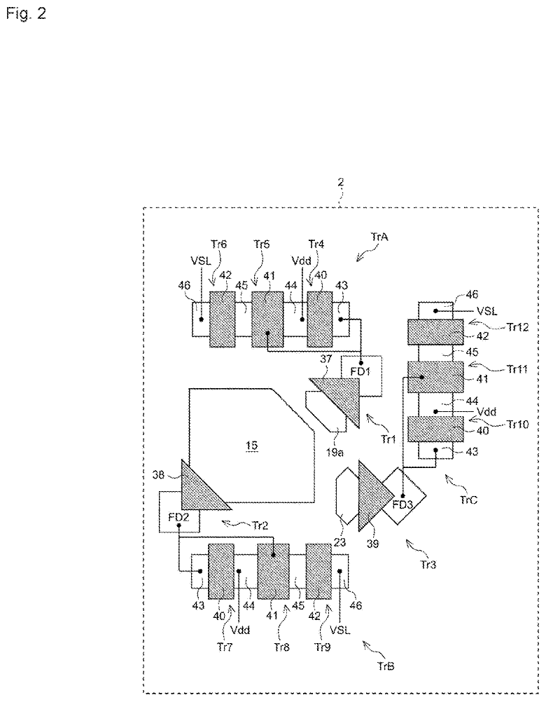

FIG. 2 shows a schematic planar configuration of the pixel 2 of the imaging element 1. As shown in FIG. 2, the pixel 2 includes a photoelectric conversion region 15 in which first to third photoelectric conversion parts for photoelectric conversion of lights having wavelengths of red, green, and blue are laminated in three layers, and a charge readout part corresponding to each photoelectric conversion part. In the present embodiment, the charge readout part is composed of first to third pixel transistors TrA, TrB, and TrC corresponding to the first to third photoelectric conversion parts. In the imaging element 1 of the present embodiment, vertical spectroscopy is performed in the pixel 2.

The first to third pixel transistors TrA, TrB, and TrC are formed around the photoelectric conversion region 15 and each is composed of four MOS type transistors. The first pixel transistor TrA outputs signal charge generated and accumulated by the first photoelectric conversion part, which will be described later, as a pixel signal and includes a first transfer transistor Tr1, a reset transistor Tr4, an amplification transistor Tr5, and a select transistor Tr6.

The second pixel transistor TrB outputs signal charge generated and accumulated by the second photoelectric conversion part, which will be described later, as a pixel signal and includes a second transfer transistor Tr2, a reset transistor Tr7, an amplification transistor Tr8, and a select transistor Tr9.

The third pixel transistor TrC outputs signal charge generated and accumulated by the third photoelectric conversion part, which will be described later, as a pixel signal and includes a third transfer transistor Tr3, a reset transistor Tr10, an amplification transistor Tr11, and a select transistor Tr12.

Each of the reset transistors Tr4, Tr7, and Tr10 includes source/drain regions 43 and 44, and a gate electrode 40. Each of the amplification transistors Tr5, Tr8, and Tr11 includes source/drain regions 44 and 45, and a gate electrode 41. Each of the select transistors Tr6, Tr9, and Tr12 includes source/drain regions 45 and 46, and a gate electrode 42.

In these pixel transistors TrA, TrB, and TrC, floating diffusion parts FD1, FD2, and FD3 are connected to one of the source/drain regions 43 of the corresponding reset transistors Tr4, Tr7, and Tr10. Further, the floating diffusion parts FD1, FD2, and FD3 are connected to the gate electrodes 41 of the corresponding amplification transistors Tr5, Tr8, and Tr11. In addition, power supply voltage wiring Vdd is connected to the source/drain regions 44 common to the reset transistors Tr4, Tr7, Tr10 and the amplification transistors Tr5, Tr8, Tr11. Further, select signal wiring VSL is connected to one of the source/drain regions 46 of the selection transistors Tr6, Tr9, and Tr12.

### <Cross-Sectional Configuration of Pixel>

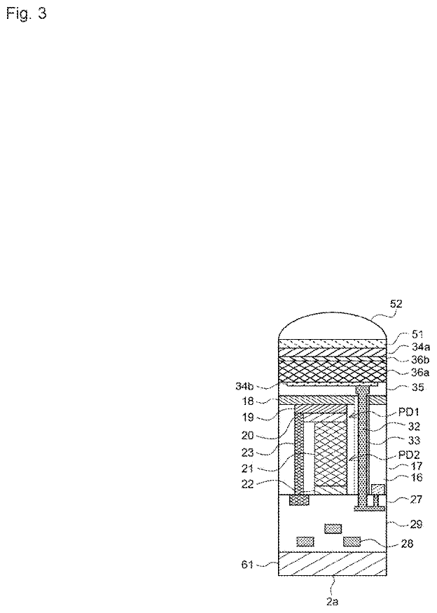

FIG. 3 shows a schematic cross-sectional configuration of a pixel 2a of the imaging element 1. In FIG. 3, the first to third pixel transistors TrA, TrB, TrC and the like are not shown.

The imaging element 1 of the present embodiment is a back-illuminated imaging device in which light is incident from the back surface side opposite to the side on which the pixel transistors are formed, which is the front surface side of a semiconductor substrate 17. In FIG. 3, the upper side is the light receiving surface side (light incident surface side) on the back surface side, and the lower side is the front surface side, which is a circuit formation surface on which pixel transistors, peripheral circuits such as logic circuits, and the like are formed. The light receiving surface and the circuit formation surface are in a positional relationship in which they face each other.

The photoelectric conversion region 15 has a configuration in which first and second photoelectric conversion parts composed of a first photodiode PD1 and a second photodiode PD2 formed on the semiconductor substrate 17, and a third photoelectric conversion part composed of an organic photoelectric conversion film 36a formed on the back surface side of the semiconductor substrate 17 are laminated in a light incident direction.

The first photodiode PD1 and the second photodiode PD2 are formed in a well region 16 that is a first conductive type (p type in the present embodiment) semiconductor region of the semiconductor substrate 17 made of silicon.

A p-type semiconductor region 18 having a high p-type impurity concentration is formed above the semiconductor substrate 17 in the figure. The first photodiode PD1 is composed of the p-type semiconductor region 18 and an n-type semiconductor region 19 having second conductive type (n-type in this embodiment) impurities formed on the light receiving surface side of the semiconductor substrate 17.

Although description will be continued here with the first conductive type as the p type and the second conductive type as the n type, the first conductive type may be the n type and the second conductive type may be the p type. When the first conductive type is the n type and the second conductive type is the p type, the present technology can be realized by appropriately replacing the p type with the n type and replacing the n type with the p type in the following description.

An electrode 23 connected to the transfer transistor Tr1 that reads out electric charge accumulated in the first photodiode PD1 to FD1 (not shown in FIG. 3) is formed such that it is in contact with the n-type semiconductor region 19.

The second photodiode PD2 is composed of an n-type semiconductor region 21 formed on the front surface side of the semiconductor substrate 17 and a high-concentration p-type semiconductor region 22 serving as a hole accumulation layer formed at the interface of the semiconductor substrate 17 on the surface side thereof. Since the p-type semiconductor region 22 is formed at the interface of the semiconductor substrate 17, dark current generated at the interface of the semiconductor substrate 17 can be suppressed.

A p-type semiconductor region 20 is formed between the first photodiode PD1 and the second photodiode PD2.

The second photodiode PD2 formed in a region farthest from the light receiving surface is a photoelectric conversion part that photoelectrically converts light having a red wavelength. In addition, the first photodiode PD1 formed on the light receiving surface side is a photoelectric conversion part that photoelectrically converts light having a blue wavelength.

In the pixel 2a of FIG. 3, the photoelectric conversion part that photoelectrically converts light having a green wavelength is composed of the organic photoelectric conversion film 36a on the semiconductor substrate 17 on the back surface side. For the organic photoelectric conversion film 36a, for example, an organic photoelectric conversion material containing a rhodamine dye, a merocyanine dye, quinacridone, or the like is used.

The upper surface of the organic photoelectric conversion film 36a is covered with a passivation film (nitride film) 36b, and the organic photoelectric conversion film 36a and the passivation film 36b are sandwiched between an upper electrode 34a and a lower electrode 34b.

A planarization film 51 is formed on the upper side of the upper electrode 34a, and an on-chip lens 52 is provided on the planarization film 51. On the other hand, an insulating film 35 for alleviating a stepped portion on the edge of the lower electrode 34b is provided in a region where the lower electrode 34b is not formed on the same plane as the lower electrode 34b. The upper electrode 34a and the lower electrode 34b are made of a light-transmitting material and are formed of a transparent conductive film such as an indium tin (ITO) film or an indium zinc oxide film.

Although the material of the organic photoelectric conversion film 36a is a material for photoelectric conversion of green light in the present embodiment, the organic photoelectric conversion film 36a may be formed of a material for photoelectric conversion of light having a wavelength of blue or red and the first photodiode PD1 and the second photodiode PD2 may be configured to correspond to other wavelengths.

For example, when the organic photoelectric conversion film 36a absorbs blue light, the first photodiode PD1 formed on the light receiving surface side of the semiconductor substrate 17 can be set as a photoelectric conversion part that photoelectrically converts green light and the second photodiode PD2 can be set as a photoelectric conversion part that photoelectrically converts red light.

When the organic photoelectric conversion film 36a absorbs red light, the first photodiode PD1 formed on the light receiving surface side of the semiconductor substrate 17 can be set as a photoelectric conversion part that photoelectrically converts blue light and the second photodiode PD2 can be set as a photoelectric conversion part that photoelectrically converts green light.

As an organic photoelectric conversion film that photoelectrically converts blue light, an organic photoelectric conversion material containing a coumaric acid dye, tris-8-hydroxyquinoline Al (Alq3), a merocyanine dye, or the like can be used. Further, as an organic photoelectric conversion film for photoelectric conversion of red light, an organic photoelectric conversion material containing a phthalocyanine dye can be used.

As in the present embodiment, it is desirable to set light to be photoelectrically converted in the semiconductor substrate 17 to blue and red and set light to be photoelectrically converted by the organic photoelectric conversion film 36a to green. This is because in this case spectral characteristics with respect to between the first photodiode PD1 and the second photodiode PD2 can be improved.

The lower electrode 34b formed on the above-mentioned organic photoelectric conversion film 36a on the side of the semiconductor substrate 17 is connected to a through-electrode 32. For the through-electrode 32, for example, Al, Ti, W or the like can be used. The through-electrode 32 is formed from the back surface side to the front surface side of the semiconductor substrate 17.

A multilayer wiring layer 27 having wiring 28 laminated in a plurality of layers (three layers in the present embodiment) is formed on the front surface side of the semiconductor substrate 17 via an interlayer insulating film 29. Further, a support substrate 61 formed in a manufacturing stage is formed on the surface of the multilayer wiring layer 27.

### <Manufacturing of Imaging Element>

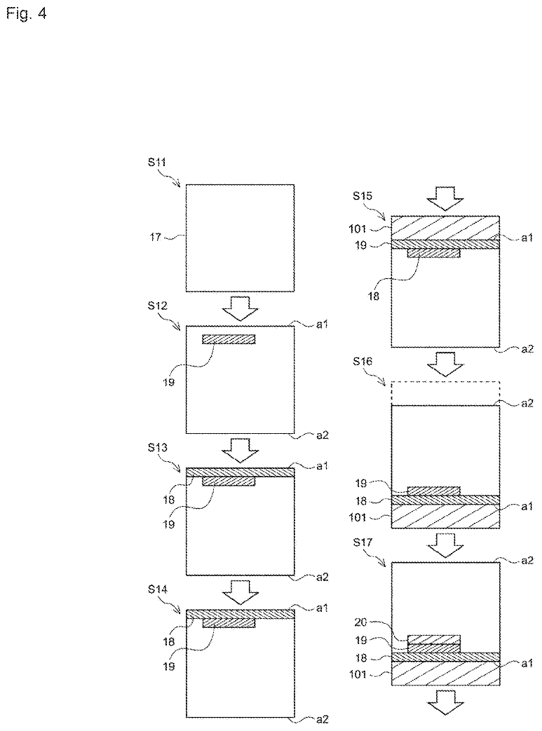

A manufacturing method of a manufacturing apparatus for manufacturing the imaging element 1 having the structure of the pixel 2a shown in FIG. 3 will be described with reference to FIG. 4 to FIG. 6.

In process S11, the semiconductor substrate 17 is prepared. As the semiconductor substrate 17, a silicon (Si) substrate can be used.

In process S12, an n-type diffusion layer corresponding to the n-type semiconductor region 19 (hereinafter, appropriately described as a first n-type diffusion layer 19) is formed on the side of the light receiving surface a1 (the side on which the on-chip lens 52 is laminated in the pixel 2a of FIG. 3). The first n-type diffusion layer is formed, for example, by ion implantation such that it has a peak within 100 nm from the surface of the semiconductor substrate 17 on the side of the light receiving surface a1.

In process S13, a p-type diffusion layer corresponding to the p-type semiconductor region 18 (hereinafter, appropriately referred to as a first p-type diffusion layer 18) is formed. The first p-type diffusion layer 18 is formed as a p-type high-concentration impurity layer in contact with the first n-type diffusion layer 19 at a shallower position in contact with the light receiving surface.

In process S14, impurities are activated by performing activation annealing using a method such as rapid thermal anneal (RTA) to form the n-type semiconductor region 19 and the p-type semiconductor region 18.

In process S15, a support substrate 101 made of, for example, silicon is attached to the side of the light receiving surface a1 of the semiconductor substrate 17.

In process S16, the semiconductor substrate 17 is turned upside down and the semiconductor substrate 17 (silicon substrate) is polished to a desired film thickness. In the subsequent process, the n-type semiconductor region 21 is formed, and if this n-type semiconductor region 21 needs to serve as a photodiode that receives light having a red wavelength, the semiconductor substrate 17 is polished to a thickness that can secure sufficient sensitivity to light having the red wavelength. The thickness that can secure sufficient sensitivity to light having the red wavelength is, for example, at least about 3 μm.

In process S17, a p-type semiconductor region 20 (hereinafter, appropriately referred to as a second p-type diffusion layer 20) serving as a potential barrier layer is formed by ion-implanting p-type impurities at a low concentration toward the n-type semiconductor region 19 (first n-type diffusion layer 19) from the side opposite to the light receiving surface side and on which the multilayer wiring layer 27 is laminated (described as the side of a circuit formation surface a2).

The second p-type diffusion layer 20 may be provided as a potential barrier layer and may be formed before the first n-type diffusion layer 19 is formed on the side of the light receiving surface a1. That is, the processing order may be changed such that processing in process S17 is performed before process 12, and thus the second p-type diffusion layer 20 is formed and then the first n-type diffusion layer 19 is formed.

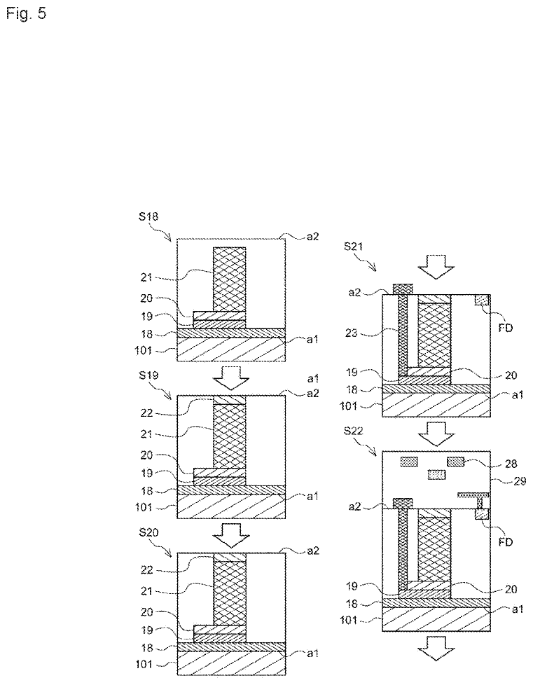

In process S18 (FIG. 5), the second n-type diffusion layer 21 is formed on the second p-type diffusion layer 20 by ion implantation from the side of the circuit formation surface a2 in the vertical direction. The second n-type diffusion layer 21 is a region serving as the n-type semiconductor region 21 constituting the second photodiode PD2. The second photodiode PD2 may be formed by stepwise ion implantation such that the n-type impurity concentration gradually increases from the second n-type diffusion layer 21 to the side of the circuit formation surface a2 of the semiconductor substrate 17.

In process S19, a region corresponding to the p-type semiconductor region 22 (hereinafter, appropriately referred to as a third p-type diffusion layer 22) is formed on the upper side (outermost surface) of the second p-type diffusion layer 20, in other words, on the side of the circuit formation surface a2 of the semiconductor substrate 17. The third p-type diffusion layer 22 is formed by ion-implanting p-type impurities at a high concentration. By providing the third p-type diffusion layer 22, dark current can be suppressed. That is, the third p-type diffusion layer 22 functions as a dark current suppression region.

In process S20, impurities are activated by performing activation annealing using a method such as rapid thermal anneal (RTA) to form the n-type semiconductor region 21 and the p-type semiconductor region 22.

By executing processing up to process S20, laminated photodiodes are formed in the vertical direction from the light receiving surface on the back surface side to the front surface side. That is, the first photodiode PD1 and the second photodiode PD2 are formed on the semiconductor substrate 17.

In process S21, the gate electrode 23, FD, and the like of a vertical transfer transistor are formed on the surface side of the circuit formation surface a2.

In process S22, for example, deposition of an interlayer insulating film 29 made of silicon oxide is performed and the multilayer wiring layer 27 made of a metal material is formed. As the metal material forming the multilayer wiring layer 27, for example, copper, tungsten, aluminum, or the like can be used.

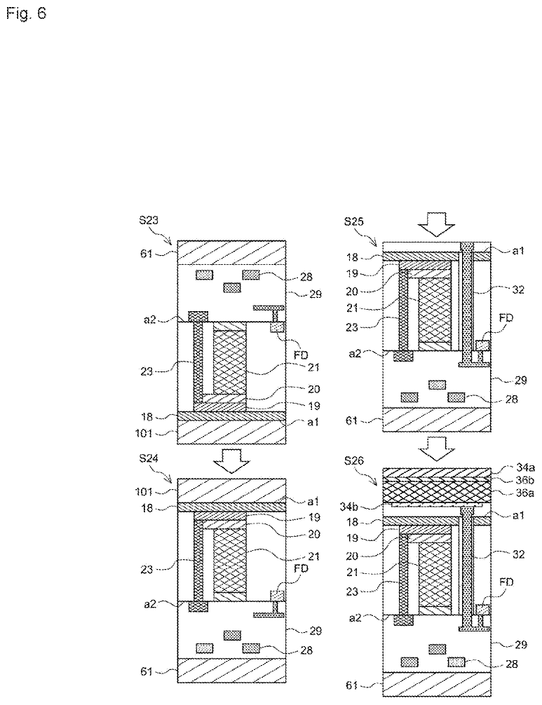

In process S23 (FIG. 6), a support substrate 61 made of, for example, silicon is attached to the upper part of the multilayer wiring layer 27.

In process S24, the element including the semiconductor substrate 17 is reversed again, and the support substrate 101 attached to the side of the light receiving surface a1 is removed.

In process S25, after patterning of a hole pattern for the through-electrode 32, the semiconductor substrate 17 is opened by dry etching. Thereafter, an insulating film 33 also serving as an antireflection film is formed on the semiconductor substrate 17 on the side of the light receiving surface a1 and the side wall of a trench opened for the through-electrode 32. As the antireflection film, a film having a high refractive index, an interface with a semiconductor layer having a low defect level, and negative fixed charge is used.

As a material having negative fixed charge, for example, hafnium oxide (HfO₂), aluminum oxide (Al₂O₃), zirconium oxide (ZrO₂), tantalum oxide (Ta₂O₅), titanium oxide (TiO₂), and the like can be used.

After the trench is formed, an insulating film such as silicon oxide is embedded by a method such as atomic layer deposition (ALD). Further, the insulating film formed at the bottom of the trench forming the through-electrode 32 is removed by a method such as dry etching. The through-electrode 32 is formed by embedding a metal material in the trench with the insulating film 33 formed on the side wall of the trench.

In process S26, the lower electrode 34b is formed in a desired region on the through-electrode 32. The lower electrode 34b is made of a transparent conductive film material, and for example, indium tin oxide (ITO) or indium zinc oxide (IZO) can be used. After formation of the lower electrode 34b, the organic photoelectric conversion film 36a is formed. Here, an organic photoelectric conversion film material that selectively absorbs green light is used as the organic photoelectric conversion film 36a, and then the upper electrode 34a made of a transparent conductive film material is formed thereon.

Although not shown, the planarization film 51, the on-chip lens 52, and the like are formed after process S26 to form (the imaging element 1 including) the pixel 2a shown in FIG. 3.

### <Impurity Concentration of Imaging Element>

As described above, (the imaging element 1 including) the pixel 2a includes the first photodiode PD1 and the second photodiode PD2. Each of the first photodiode PD1 and the second photodiode PD2 is formed by ion implantation. Further, ion implantation is performed from the side of the light receiving surface a1 of the semiconductor substrate 17 and the side of the circuit formation surface a2.

As described above, in processes S12 to S14 (FIG. 4), the first p-type diffusion layer 18 and the first n-type diffusion layer 19 constituting the first photodiode PD1 are formed by ion implantation from the side of the light receiving surface a1. In addition, in processes S18 to S20 (FIG. 5), the second n-type diffusion layer 21 and the third p-type diffusion layer 22 constituting the second photodiode PD2 are formed by ion implantation from the side of the circuit formation surface a2.

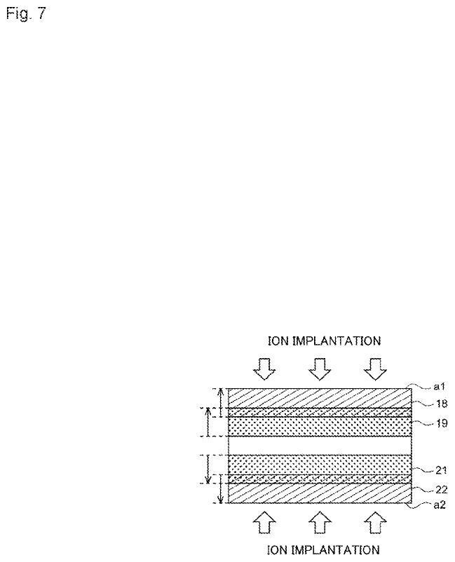

By setting the surface on which ion implantation is performed when the first photodiode PD1 is formed and the surface on which ion implantation is performed when the second photodiode PD2 is formed as different surfaces in this way, the first photodiode PD1 and the second photodiode PD2 can be formed such that they have a steep impurity profile. This will be described with reference to FIG. 7.

FIG. 7 is a diagram illustrating the p-type semiconductor region 18 (first p-type diffusion layer 18), the n-type semiconductor region 19 (first n-type diffusion layer 19), the n-type semiconductor region 21 (second n-type diffusion layer 21), and the p-type semiconductor region 22 (third p-type diffusion layer 22) in the pixel 2a shown in FIG. 3.

Meanwhile, FIG. 7 illustrates the regions using diagonal lines or the like different from the pixel 2a shown in FIG. 3 for easy viewing. Although not explicitly shown in FIG. 7, the p-type semiconductor region 20 (second p-type diffusion layer 20) is present between the n-type semiconductor region 19 and the n-type semiconductor region 21.

In FIG. 7, it is assumed that the upper side is the side of the light receiving surface a1 and the lower side is the side of the circuit formation surface a2. As described above, the first p-type diffusion layer 18 and the first n-type diffusion layer 19 are formed by ion implantation from the side of the light receiving surface a1.

Accordingly, as indicated by arrows on the left side of the figure, the impurity concentration is higher on the side of the light receiving surface a1 in each diffusion layer. The arrows shown in the figure indicate that the impurity concentration increases in the directions indicated thereby.

View from the side of the light receiving surface a1 of the semiconductor substrate 17. In the first p-type diffusion layer 18, the p-type impurity concentration is higher on the side of the light receiving surface a1 and decreases as the distance from the side of the light receiving surface a1 increases (as it becomes deeper). Similarly, in the first n-type diffusion layer 19, the n-type impurity concentration is higher on the side of the light receiving surface a1 and decreases as the distance from the side of the light receiving surface a1 increases (as it becomes deeper).

The first photodiode PD1 is a region having an impurity profile in which the impurity concentration decreases in the direction in which the distance from the light receiving surface a1 increases when viewed from the side of the light receiving surface a1. In other words, the first photodiode PD1 is a region having an impurity profile having an impurity concentration peak on the side of the light receiving surface a1.

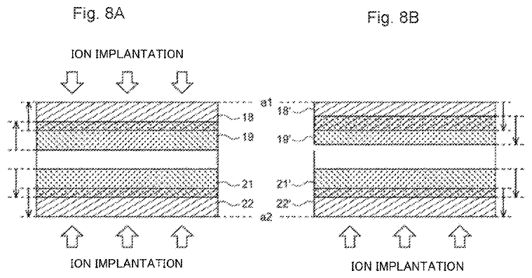

Although there is a portion where the first p-type diffusion layer 18 and the first n-type diffusion layer 19 overlap, this overlapping portion can be formed thinner than the corresponding portion in a conventional imaging element 1′ which will be described with reference to FIG. 8B. That is, it is possible to form the first photodiode PD1 having a steep impurity profile.

Next, view from the side of the circuit formation surface a2 of the semiconductor substrate 17. In the third p-type diffusion layer 22, the p-type impurity concentration is higher on the side of the circuit formation surface a2 and decreases as the distance from the side of the circuit formation surface a2 side increases (as it becomes deeper). Similarly, in the second n-type diffusion layer 21, the n-type impurity concentration is higher on the side of the circuit formation surface a2 and decreases as the distance from the side of the circuit formation surface a2 (as it becomes deeper).

The second photodiode PD2 is a region having an impurity profile in which the impurity concentration decreases in the direction in which the distance from the circuit formation surface a2 increases when viewed from the side of the circuit formation surface a2. In other words, the second photodiode PD2 is a region having an impurity profile having an impurity concentration peak on the side of the circuit formation surface a2.

Although description is as above when viewed from the side of the circuit formation surface a2, description is as follows when viewed from the side of the light receiving surface a1. In the third p-type diffusion layer 22, the p-type impurity concentration is lower on the side of the light receiving surface a1 and increases as the distance from the side of the light receiving surface a1 increases (as it becomes deeper). Similarly, in the second n-type diffusion layer 21, the n-type impurity concentration is lower on the side of the light receiving surface a1 and increases as the distance from the side of the light receiving surface a1 increases (as it becomes deeper).

The second photodiode PD2 is a region having an impurity profile in which the impurity concentration increases in the direction in which the distance from the light receiving surface a1 increases when viewed from the side of the light receiving surface a1.

The impurity profile of the first photodiode PD1 and the impurity profile of the second photodiode PD2 are different. That is, as described above, the first photodiode PD1 has a higher impurity concentration on the side of the light receiving surface a1, whereas the second photodiode PD2 has a lower impurity concentration on the side of the light receiving surface a1. In this manner, the first photodiode PD1 and the second photodiode PD2 are oriented in different directions when the degrees of impurity concentrations are observed. Further, the first photodiode PD1 and the second photodiode PD2 are in a relationship in which the sides on which the impurity concentrations are lower face each other when the impurity concentrations are observed.

The pixel 2a manufactured through the above-mentioned processes is compared with the pixel 2a manufactured through processes (conventional processes) different from the above-mentioned processes with reference to FIG. 8. A of FIG. 8 is the same diagram as FIG. 7 and shows the pixel 2a manufactured through the above-mentioned processes. B of FIG. 8 is a diagram showing a pixel 2a′ (described with a dash to distinguish it from the pixel 2a manufactured through the above-mentioned processes) manufactured through conventional processes.

The pixel 2a shown in A of FIG. 8 is the same as that in the case described with reference to FIG. 7, and thus description thereof is omitted. The pixel 2a′ shown in B of FIG. 8 also has the same configuration as that of the pixel 2a shown in A of FIG. 8, in which a first p-type diffusion layer 18′, a first n-type diffusion layer 19′, a second p-type diffusion layer 20′(not shown), a second n-type diffusion layer 21′, and a third p-type diffusion layer 22′ are sequentially laminated on the side of the light receiving surface a1.

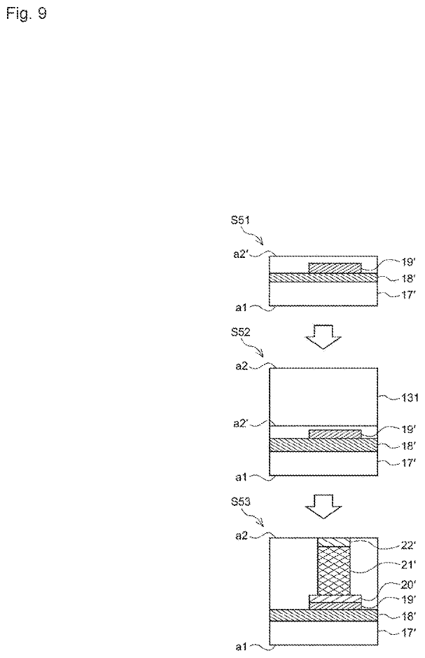

In the conventional method of manufacturing the pixel 2a′, the first p-type diffusion layer 18′, the first n-type diffusion layer 19′, the second p-type diffusion layer 20′(not shown), the second n-type diffusion layer 21′, and the third p-type diffusion layer 22′ are formed by ion implantation from the lower side in the figure, that is, the side of the circuit formation surface a2. This manufacturing method will be briefly described with reference to FIG. 9.

In process S51, the first p-type diffusion layer 18′ and the first n-type diffusion layer 19′ are formed. In FIG. 9, the lower side of the semiconductor substrate 17 is the light receiving surface a1, and the upper side is a temporary circuit formation surface a2′. In process S51, ions are implanted from the side of the circuit formation surface a2′ and activation annealing is executed to form the first p-type diffusion layer 18′ and the first n-type diffusion layer 19′. In process S51, the first p-type diffusion layer 18′ and the first n-type diffusion layer 19′ are formed near the surface of the semiconductor substrate 17′.

In process S52, silicon is added to the semiconductor substrate 17′ through epitaxial growth for growing a crystal layer having an aligned crystal axis to form a silicon layer 131. The silicon layer 131 is a portion corresponding to the circuit formation surface a2 from the temporary circuit formation surface a2′ in the figure.

In process S53, the second p-type diffusion layer 20′, the second n-type diffusion layer 21′, and the third p-type diffusion layer 22′ are formed. The second p-type diffusion layer 20′, the second n-type diffusion layer 21′, and the third p-type diffusion layer 22′ are formed by executing ion implantation and activation annealing from the side of the circuit formation surface a2.

The state of the pixel 2a′ in process S52 is substantially the same as the state of the pixel 2a after processing in process S16 (FIG. 4) end. Since processing subsequent to process S53 can be performed in the same manner as processing subsequent to process S17, description thereof is omitted here.

In the conventional manufacturing method, after the first p-type diffusion layer 18′ and the first n-type diffusion layer 19′ are formed, the silicon layer 131 forming the second p-type diffusion layer 20′, the second n-type diffusion layer 21′, and the third p-type diffusion layer 22′ is formed through epitaxial growth. Since epitaxial growth is performed through high-temperature heat treatment, it also affects the formed first p-type diffusion layer 18′ and the first n-type diffusion layer 19′.

The first p-type diffusion layer 18′ shown in process S51 of FIG. 9 and the first p-type diffusion layer 18′ shown in process S52 are compared. Impurities are diffused in the first p-type diffusion layer 18′ shown in process S51 by heat treatment during epitaxial growth.

As a result, the vertical width of the first p-type diffusion layer 18′ shown in process S52 becomes wider than that of the first p-type diffusion layer 18′ shown in process S51. Further, the vertical width of the first n-type diffusion layer 19′ shown in process S52 becomes wider than that of the first n-type diffusion layer 19′ shown in process S51.

Refer to B of FIG. 8 again. The region where the first p-type diffusion layer 18′ and the first n-type diffusion layer 19′ overlap is larger than the region where the first p-type diffusion layer 18 and the first n-type diffusion layer 19 overlap shown in A of FIG. 8. This is because the first p-type diffusion layer 18′ and the first n-type diffusion layer 19′ become larger and thus the region where the first p-type diffusion layer 18′ and the first n-type diffusion layer 19′ overlap is enlarged, as described above.

In the pixel 2a′ manufactured by the conventional method, the region where the first p-type diffusion layer 18′ and the first n-type diffusion layer 19′ overlap is large, and thus it is difficult to form a steep impurity profile. However, in the pixel 2a to which the present embodiment is applied, the region where the first p-type diffusion layer 18 and the first n-type diffusion layer 19 overlap can be reduced, and thus a steep impurity profile can be formed.

In the pixel 2a′ manufactured by the conventional method and the pixel 2a to which the present embodiment is applied, impurity concentration profiles are different in addition to the difference in the degree of overlapping between the p-type diffusion layer and the n-type diffusion layer (whether or not it is steep).

Refer to B of FIG. 8. View from the side of the light receiving surface a1 of the semiconductor substrate 17′. In the first p-type diffusion layer 18′, the p-type impurity concentration is lower on the side of the light receiving surface a1 and increases as the distance from the side of the light receiving surface a1 increases (as it becomes deeper). Similarly, in the first n-type diffusion layer 19′, the n-type impurity concentration is lower on the side of the light receiving surface a1 and increases as the distance from the side of the light receiving surface a1 increases (as it becomes deeper).

The first photodiode PD1′ is a region having an impurity profile in which the impurity concentration increases in the direction in which the distance from the light receiving surface a1 increases when viewed from the side of the light receiving surface a1. In view of this, it differs from the impurity profile of the pixel 2a to which the present technology is applied shown in A of FIG. 8.

In addition, the second n-type diffusion layer 21′ and the third p-type diffusion layer 22′ are also regions having impurity profiles in which the impurity concentrations increase in the direction in which the distance from the light receiving surface a1 increases when viewed from the side of the light receiving surface a1. That is, in the third p-type diffusion layer 22′, the p-type impurity concentration is lower on the side of the light receiving surface a1 and increases as the distance from the side of the light receiving surface a1 increases (as it becomes deeper). Similarly, in the second n-type diffusion layer 21′, the n-type impurity concentration is lower on the side of the light receiving surface a1 and increases as the distance from the side of the light receiving surface a1 increases (as it become deeper).

The second photodiode PD2′ is a region having an impurity profile in which the impurity concentration increases in the direction in which the distance from the light receiving surface a1 increases when viewed from the side of the light receiving surface a1.

In the pixel 2a′ manufactured by the conventional method, the first photodiode PD1′ and the second photodiode PD2′ have the same impurity profile. That is, as described above, the first photodiode PD1′ has a lower impurity concentration on the side of the light receiving surface a1, and the second photodiode PD2′ also has a lower impurity concentration on the side of the light receiving surface a1. In this manner, the first photodiode PD1′ and the second photodiode PD2′ are oriented in the same direction when the impurity concentrations are observed.

As described above, even the impurity profiles of the pixel 2a′ manufactured by the conventional method and the pixel 2a to which the present technology is applied are different.

According to the present technology, it is possible to form the photodiodes laminated in the semiconductor substrate 17 such that they have a steep profile. Further, it is possible to form the steep profile even if the pixel 2a is miniaturized, and thus an imaging device (image sensor) with a high SN ratio in which photodiodes are laminated in the vertical direction can be realized.

For example, when a blue light photodiode is formed on the back surface side (the side of the light receiving surface a1), the impurity profile of the blue light photodiode can be formed steeply. Further, even in a fine pixel, it is possible to realize an imaging device (image sensor) in which photodiodes are laminated in the vertical direction and which have a large saturation signal amount of blue light and a high SN ratio.

### <Another Method of Manufacturing Imaging Element>

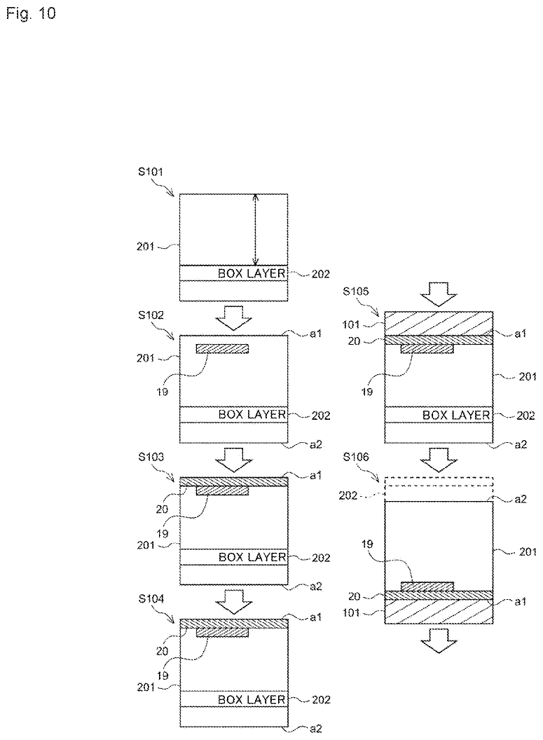

Another manufacturing method of the manufacturing apparatus for manufacturing the pixel 2a (imaging element) shown in FIG. 3 will be described with reference to FIG. 10.

As another manufacturing method, a case in which silicon on insulator (SOI) substrate 201 is used as the semiconductor substrate 17 will be described. In step S101, the SOI substrate 201 is prepared. The SOI substrate 201 is a substrate having a structure in which a layer of a silicon oxide film called a BOX layer 202 is inserted into a silicon substrate. The silicon layer on the BOX layer 202 and the silicon layer under the BOX layer 202 are characterized in that they are insulated by the BOX layer 202 of the silicon oxide film.

In the figure, it is assumed that the upper surface is the light receiving surface a1, and the lower surface is the circuit formation surface a2. The film thickness from the BOX layer 202 to the light receiving surface a1 is a desired film thickness. The desired film thickness can be a film thickness desired to be a final film thickness of the semiconductor substrate 17.

In step S102, the first n-type diffusion layer 19 corresponding to the n-type semiconductor region 19 is formed on the side of the light receiving surface a1.

In step S103, the first p-type diffusion layer 18 corresponding to the p-type semiconductor region 18 is formed. The first p-type diffusion layer 18 is formed as a p-type high-concentration impurity layer in contact with the first n-type diffusion layer 19 at a shallower position in contact with the light receiving surface.

In step S104, impurities are activated by performing activation annealing using a method such as rapid thermal anneal (RTA) to form the n-type semiconductor region 19 and the p-type semiconductor region 18.

In step S105, the support substrate 101 made of, for example, silicon is attached to the light receiving surface side of the SOI substrate 201 (semiconductor substrate 17).

In step S106, the SOI substrate 201 is turned upside down and polished until the SOI substrate 201 has a desired film thickness. When the SOI substrate 201 is used, it is polished until the BOX layer 202 is eliminated.

The state of the pixel 2a when processing of process S106 ends is the same as the state of the pixel 2a when processing of process S16 (FIG. 4) ends. Since processing subsequent to process S106 can be performed in the same manner as processing subsequent to process S17, description thereof is omitted here.

In this manner, even when the SOI substrate 201 is used, the pixel 2a having the structure as shown in FIG. 3 and the impurity profile described with reference to FIG. 7 can be manufactured.

### <Another Configuration of Imaging Element>

The pixel 2a shown in FIG. 3 has a configuration in which the first photodiode PD1 and the second photodiode PD2 (first and second photoelectric conversion parts) are provided in the silicon substrate 17 and the third photoelectric conversion part made of the organic photoelectric conversion film 36a is provided on the silicon substrate 17.

A pixel 2b in which the third photoelectric conversion part made of the organic photoelectric conversion film 36a is also formed in the silicon substrate 17 and the first to third photoelectric conversion parts are formed in the silicon substrate 17 can be configured.

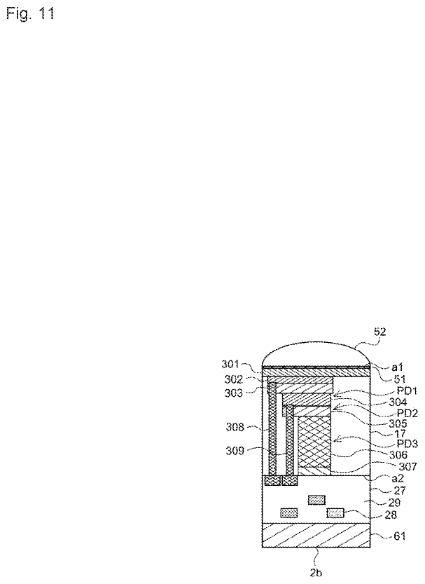

FIG. 11 is a diagram showing the configuration of the pixel 2b and shows a configuration example of the pixel 2b in which the first to third photoelectric conversion parts are formed in the silicon substrate 17. The pixel 2b shown in FIG. 11 has a structure in which the on-chip lens 52, the planarization film 51, the semiconductor substrate 17, and the multilayer wiring layer 27 are sequentially laminated from the upper side in the figure.

Further, in the semiconductor substrate 17, a p-type semiconductor region 301, an n-type semiconductor region 302, a p-type semiconductor region 303, an n-type semiconductor region 304, a p-type semiconductor region 305, an n-type semiconductor region 306, and a p-type semiconductor region 307 are laminated sequentially from the light receiving surface side. An electrode 308 is provided as an electrode of a transistor that transfers charge accumulated in the n-type semiconductor region 302, and an electrode 309 is provided as an electrode of a transistor that transfers charge accumulated in the n-type semiconductor region 304.

In the semiconductor substrate 17, when the side of the multilayer wiring layer 27 is viewed from the side of the on-chip lens 52, a first photodiode PD1, a second photodiode PD2, and a third photodiode PD3 are laminated.

The first photodiode PD1 is a region including an n-type semiconductor region 302. The n-type semiconductor region 302 is also appropriately described as a first n-type diffusion layer 302. Further, the p-type semiconductor region 301 formed on the n-type semiconductor region 302 is also described as a first p-type diffusion layer 301.

The second photodiode PD2 is a region including the n-type semiconductor region 304. The n-type semiconductor region 304 is also appropriately described as a second n-type diffusion layer 304. Further, the p-type semiconductor region 303 formed on the n-type semiconductor region 304 is also described as a second p-type diffusion layer 303.

The third photodiode PD3 is a region including the n-type semiconductor region 306. The n-type semiconductor region 306 is also appropriately described as a third n-type diffusion layer 306. Further, the p-type semiconductor region 305 formed on the n-type semiconductor region 306 is also described as a third p-type diffusion layer 305. Further, the p-type semiconductor region 307 formed below the n-type semiconductor region 306 is also described as a fourth p-type diffusion layer 307.

The component corresponding to the third photoelectric conversion part made of the organic photoelectric conversion film 36a of the pixel 2b shown in FIG. 3 is the first photodiode PD1 formed in the silicon substrate in the pixel 2b shown in FIG. 11.

In this manner, the present technology can be applied to the pixel 2b in which the first photodiode PD1, the second photodiode PD2, and the third photodiode PD3 are laminated in the silicon substrate.

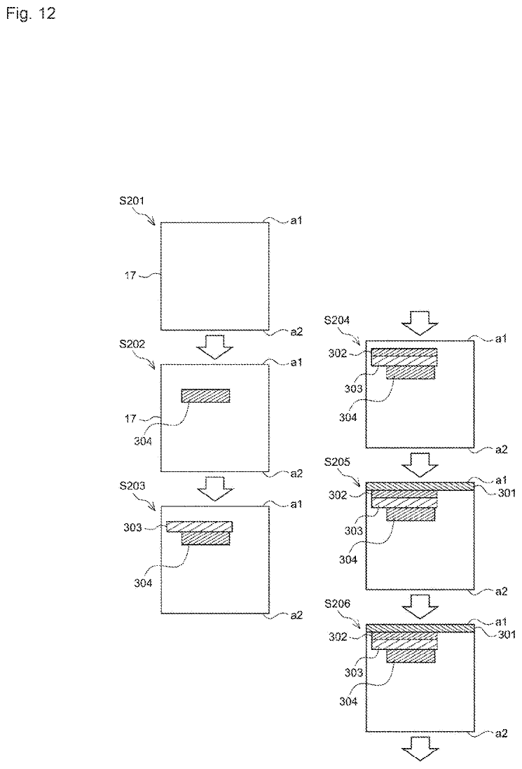

A manufacturing method of a manufacturing apparatus for manufacturing (the imaging element 1 including) the pixel 2b shown in FIG. 11 will be described with reference to FIG. 12 to FIG. 14.

In process S201, the semiconductor substrate 17 is prepared. As the semiconductor substrate 17, a silicon (Si) substrate can be used. Further, an SOI substrate may be used as the semiconductor substrate 17.

In step S202, the second n-type diffusion layer 304 corresponding to the n-type semiconductor region 304 is formed by ion implantation on the side of the light receiving surface a1.

In step S203, the second p-type diffusion layer 303 corresponding to the p-type semiconductor region 303 is formed on the side of the light receiving surface a1. The second p-type diffusion layer 303 functions as a potential barrier layer and is formed by ion-implanting p-type impurities at a low concentration.

In step S204, the first n-type diffusion layer 302 corresponding to the n-type semiconductor region 302 is formed on the side of the light receiving surface a1. For example, the first n-type diffusion layer 302 is formed by ion implantation such that it has a peak within 100 nm from the surface of the semiconductor substrate 17 on the side of the light receiving surface a1.

In step S205, the first p-type diffusion layer 301 corresponding to the p-type semiconductor region 301 is formed. The first p-type diffusion layer 301 is formed as a p-type high-concentration impurity layer in contact with the first n-type diffusion layer 302 at a shallower position in contact with the light receiving surface.

In step S206, impurities are activated by performing activation annealing using a method such as rapid thermal anneal (RTA) to form the p-type semiconductor region 301, the n-type semiconductor region 302, the p-type semiconductor region 303, and the n-type semiconductor region 304.

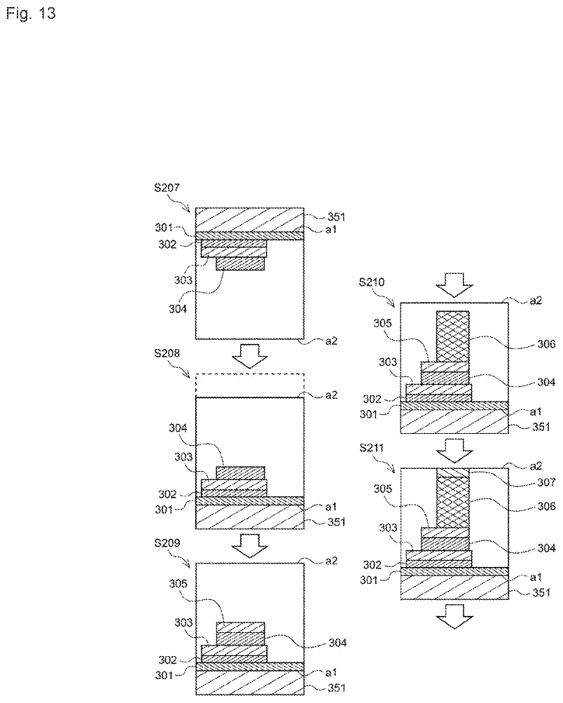

In step S207 (FIG. 13), a support substrate 351 made of, for example, silicon is attached to the light receiving surface side of the semiconductor substrate 17.

In process S208, the semiconductor substrate 17 (silicon substrate) is turned upside down and polished to a desired film thickness.

In step S209, p-type impurities are ion-implanted at a low concentration from the side of the circuit formation surface a2 which is opposite to the side of the light receiving surface and on which the multilayer wiring layer 27 is laminated to the upper side of the second n-type diffusion layer 304 to form the p-type semiconductor region 305 (third p-type diffusion layer 305) serving as a potential barrier layer.

In step S210, the third n-type diffusion layer 306 is formed by ion implantation in the vertical direction on the third p-type diffusion layer 305 on the side of the circuit formation surface a2. The third n-type diffusion layer 306 is a region forming the third photodiode PD3. The third photodiode PD3 may be formed by stepwise ion implantation such that the n-type impurity concentration gradually increases from the third n-type diffusion layer 306 to the side of the circuit formation surface a2 of the semiconductor substrate 17.

In step S211, a fourth p-type diffusion layer 307 corresponding to the p-type semiconductor region 307 is formed on the upper side (outermost surface) of the third n-type diffusion layer 306, in other words, on the side of the circuit formation surface a2 of the semiconductor substrate 17. The fourth p-type diffusion layer 307 is formed by ion-implanting p-type impurities at a high concentration. By providing the fourth p-type diffusion layer 307, dark current can be suppressed. That is, the fourth p-type diffusion layer 307 functions as a dark current suppression region.

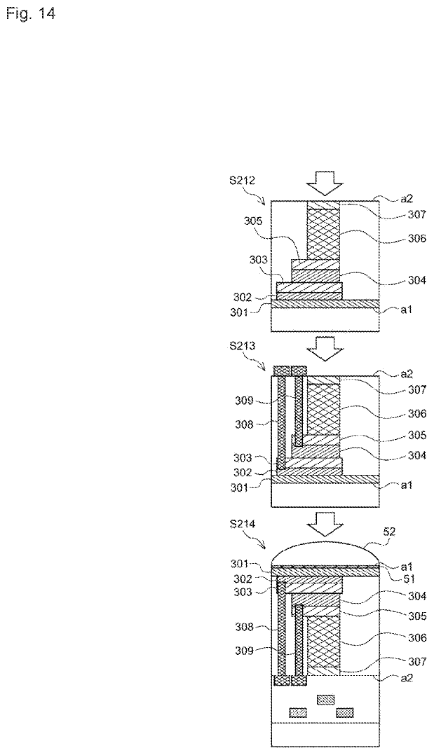

In step S212 (FIG. 14), impurities are activated by performing activation annealing using a method such as rapid thermal anneal (RTA) to form the n-type semiconductor region 306 and the p-type semiconductor region 307.

By executing processing up to process S212, laminated photodiodes are formed in the vertical direction from the light receiving surface on the back surface side to the front surface side. That is, the first photodiode PD1, the second photodiode PD2, and the third photodiode PD3 are formed on the semiconductor substrate 17.

In process S213, the gate electrode 308,309, FD, and the like of a vertical transfer transistor are formed on the surface side of the circuit formation surface a2.

In process S214, for example, deposition of an interlayer insulating film 29 made of silicon oxide is performed and the multilayer wiring layer 27 made of a metal material is formed. After the multilayer wiring layer 27 is formed, the support substrate 61 made of, for example, silicon is attached to the upper part of the formed multilayer wiring layer 27.

The element is reversed again and the support substrate 351 attached to the side of the light receiving surface a1 is removed. Then, the planarization film 51, the on-chip lens 52, and the like are formed on the light receiving surface a1, and thus (the imaging element 1 including) the pixel 2b shown in FIG. 11 is formed.

In this manner, even when the pixel 2b in which the three layers of photodiode PDs are laminated is formed in the silicon substrate 17, each of the photodiode PDs can be formed as a photodiode having a steep impurity profile as in the case described with reference to FIG. 7 and FIG. 8.

In the manufacturing process with reference to FIG. 12 to FIG. 14, a process of performing epitaxial growth is not performed after the p-type diffusion layers and the n-type diffusion layers are formed. Accordingly, it is possible to prevent impurities in the p-type diffusion layer and the n-type diffusion layer from being activated by heat treatment in the epitaxial growth process.

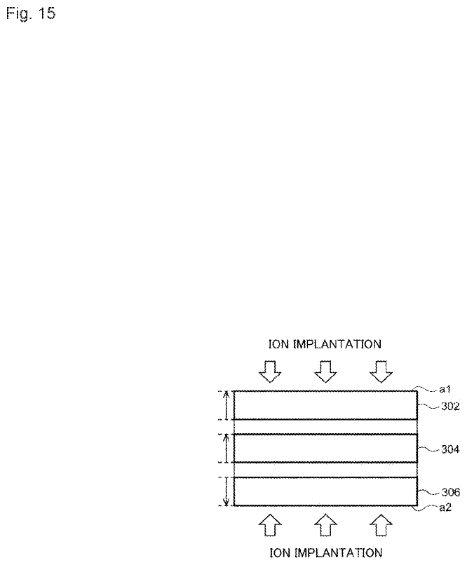

The impurity concentrations of the first photodiode PD1, the second photodiode PD2, and the third photodiode PD3 will be described with reference to FIG. 15. FIG. 15 shows the first n-type diffusion layer 302, the second n-type diffusion layer 304, and the third n-type diffusion layer 306. Arrows shown on the left side of the figure indicate the directions of the degrees of impurity concentrations.

Since the first n-type diffusion layer 302 is formed by ion implantation from the side of the light receiving surface a1 in step S204 (FIG. 12), it is formed as a region having a high impurity concentration on the side of the light receiving surface a1.

Since the second n-type diffusion layer 304 is formed by implanting ions from the side of the light receiving surface a1 in step S202 (FIG. 12), it is formed as a region having a high impurity concentration on the side of the light receiving surface a1.

Although not shown, the first p-type diffusion layer 301 and the second p-type diffusion layer 303 are also formed by ion implantation from the side of the light receiving surface a1 like the first n-type diffusion layer 302 and the second n-type diffusion layer 304, and thus they are formed as regions having a high impurity concentration on the side of the light receiving surface a1.

Since the third n-type diffusion layer 306 is formed by ion implantation from the side of the circuit formation surface a2 in step S210 (FIG. 13), it is formed as a region having a high impurity concentration on the side of the circuit formation surface a2. In other words, the third n-type diffusion layer 306 is formed as a region having a low impurity concentration on the side of the light receiving surface a1.

Although not shown, the third p-type diffusion layer 305 and the fourth p-type diffusion layer 307 are also formed by ion implantation from the side of the circuit formation surface a2 like the third n-type diffusion layer 306, and thus they are formed as regions having a high impurity concentration on the side of the circuit formation surface a2.

(The first photodiode PD1 including) the first n-type diffusion layer 302 and (the second photodiode PD2 including) the second n-type diffusion layer 304 have peaks with high impurity concentrations on the side of the light receiving surface a1 and impurity profiles in which impurities spread toward the side of the circuit formation surface a2.

(The third photodiode PD3 including) the third n-type diffusion layer 306 has a peak with a high impurity concentration on the side of the circuit formation surface a2 and an impurity profile in which impurities spread toward the side of the light receiving surface a1.

In this manner, the pixel 2b in the second embodiment can also be formed by laminating photodiodes having concentration distributions in different directions in a silicon substrate like the pixel 2a in the first embodiment.

Further, the pixel 2b having such an impurity profile can be used as an image sensor having a high SN ratio even if it is configured as a fine pixel.

### <Another Configuration of Pixel>

A pixel 2c having a structure in which a high refractive index layer is provided in the pixel 2a shown in FIG. 3 or the pixel 2b shown in FIG. 11 will be described.

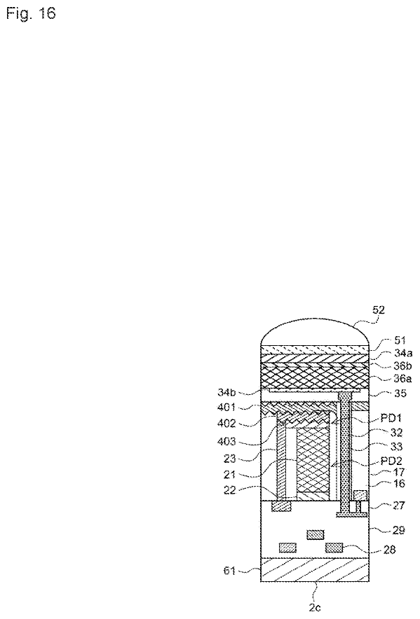

FIG. 16 is a diagram showing the pixel 2c in which a high refractive index layer is provided in the pixel 2a shown in FIG. 3. The high refractive index layer is formed by a p-type semiconductor region 401 corresponding to the p-type semiconductor region 18 in the pixel 2a shown in FIG. 3 and a n-type semiconductor region 402 corresponding to the n-type semiconductor region 19.

The p-type semiconductor region 401 is formed in a shape having uneven surfaces on the side of the light receiving surface a1 and the side of the circuit formation surface a2. Since the p-type semiconductor region 401 is configured in a shape having uneven surfaces, the n-type semiconductor region 402 is also formed in a shape having uneven surfaces on the side of the light receiving surface a1 and the side of the circuit formation surface a2. Further, since the n-type semiconductor region 402 is configured in a shape having uneven surfaces, the surface of the p-type semiconductor region 403 on the side of the light receiving surface a1 is also formed as an uneven surface.

By forming the p-type semiconductor region 401 and the n-type semiconductor region 402 having uneven shapes, incident light is incident on the silicon substrate 17 at an angle. For example, light incident on the silicon substrate 17 at a right angle is refracted due to the uneven structures of the p-type semiconductor region 401 and the n-type semiconductor region 402, converted into light having a predetermined angle, and incident on the silicon substrate 17.

In other words, light incident on the pixel 2c is scattered by the p-type semiconductor region 401 and the n-type semiconductor region 402 having uneven structures and is incident on the pixel 2c. By scattering the incident light, more light travels in the direction of the side wall of the pixel 2c. Although not shown in FIG. 16, when a pixel isolation part having a reflection function is provided between the pixels 2c, light incident on the pixels 2c is scattered by the high refractive index layer and reflected by the pixel isolation part and thus returned to pixels 2c.

Further, as the number of reflections increases, the optical distance for silicon absorption is extended, and thus the sensitivity can be improved. Since the optical distance for silicon absorption can be extended, it is possible to form a structure that increases an optical path length and efficiently focus even incident light with a long wavelength on a photodiode PD, and thus the sensitivity can be improved even for incident light having a long wavelength.

Therefore, when a plurality of photodiodes are formed in the silicon substrate 17, and incident light having a long wavelength, such as red light, is focused by a photodiode near the side of the circuit formation surface a2 (photodiode located far from the light receiving surface a1) as described above, the incident light having a long wavelength can be efficiently focused, and thus the sensitivity can be improved.

Although the high refractive index layer is provided on the side of the light receiving surface a1 in the case of the pixel 2c shown in FIG. 16, the high refractive index layer may be provided on both the side of the light receiving surface a1 and the side of the circuit formation surface a2. Further, the pixel 2c in which the high refractive index layer is provided only on the side of the circuit formation surface a2 can also be formed.

The high refractive index layer can be formed to have a desired uneven shape using, for example, a dry etching method or a wet etching method. For example, when the pixel 2c shown in FIG. 16 is manufactured on the basis of the manufacturing process described with reference to FIG. 4 to FIG. 6, processing the surface (light receiving surface a1) of the silicon substrate 17 into a shape with an uneven surface using a dry etching method or a wet etching method is performed as a process before processing of process S12 (FIG. 4) is executed.

The n-type semiconductor region 402 (corresponding to the n-type semiconductor region 19 in FIG. 4) formed by ion implantation in step S12 is also formed as a layer having an uneven shape by forming an uneven shape on the surface of the silicon substrate 17. Further, the p-type semiconductor region 401 (corresponding to the p-type semiconductor region 18 in FIG. 4) formed by ion implantation in step S13 is also formed as a layer having an uneven shape.

In this manner, the p-type semiconductor region 401 and the n-type semiconductor region 402 having uneven shapes can be formed. The process after forming the p-type semiconductor region 401 and the n-type semiconductor region 402 having uneven shapes can be performed in the same manner as in the case described with reference to FIG. 4 to FIG. 6, and thus the pixel 2c shown in FIG. 16 can be manufactured by performing the same process.

If the pixel 2c shown in FIG. 16 is manufactured by the conventional manufacturing method, for example, the manufacturing method described with reference to FIG. 9, the first photodiode PD1 and the second photodiode PD2 in the pixel 2c are formed by ion implantation from the side of the circuit formation surface a2. When the high refractive index layer is formed by the conventional manufacturing method, the high refractive index layer is formed by processing from the light receiving surface a1.

In the case of such a manufacturing process, there is a possibility that damage is caused by a processing process when the high refractive index layer is formed or the p-type semiconductor region 401 is removed by processing. Accordingly, characteristics such as dark current may deteriorate.

However, according to the manufacturing method to which the present technology is applied, the high refractive index layer can be formed without deteriorating characteristics, and the pixel 2c in which a plurality of photodiodes having the high refractive index layer are laminated can be formed, as described above.

According to the present technology, it is possible to form the photodiodes laminated in the semiconductor substrate 17 such that they have a steep profile. Further, it is possible to form the steep profile even if the pixel 2a is miniaturized, and thus an imaging device (image sensor) with a high SN ratio in which photodiodes are laminated in the vertical direction can be realized.

### <Examples of Application to Electronic Apparatuses>

The present technology is not limited to application to an imaging element. That is, the present technology can be applied to all electronic apparatuses using an imaging element for an image capture unit (photoelectric conversion part), such as an imaging device such as a digital still camera or a video camera, a portable terminal device having an imaging function, and a copier using an imaging element for an image reader. The imaging element may be in the form of one chip or may be in the form of a module having an imaging function in which an imaging unit and a signal processing unit or an optical system are packaged together.

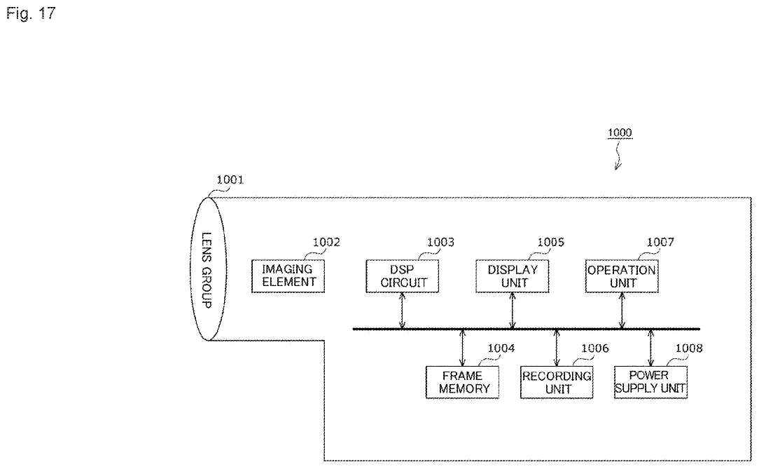

FIG. 17 is a block diagram showing a configuration example of an imaging device as an electronic apparatus to which the present technology is applied.

An imaging element 1000 of FIG. 17 includes an optical unit 1001 including a lens group and the like, an imaging element (imaging device) 1002 adopting the configuration of the imaging element 1 of FIG. 1, and a digital signal processor (DSP) circuit 1003 that is a camera signal processing circuit. Further, the imaging element 1000 also includes a frame memory 1004, a display unit 1005, a recording unit 1006, an operation unit 1007, and a power supply unit 1008. The DSP circuit 1003, the frame memory 1004, the display unit 1005, the recording unit 1006, the operation unit 1007, and the power supply unit 1008 are connected to each other via a bus line 1009.

The optical unit 1001 captures incident light (image light) from an object and forms an image on an imaging surface of the imaging element 1002. The imaging element 1002 converts the amount of incident light formed on the imaging surface by the optical unit 1001 into an electric signal in units of pixels and outputs the electric signal as a pixel signal. As the imaging element 1002, the imaging element 1 of FIG. 1 can be used.

The display unit 1005 is configured as, for example, a thin display such as a liquid crystal display (LCD) or an organic electroluminescence (EL) display and displays a moving image or a still image captured by the imaging element 1002. The recording unit 1006 records a moving image or a still image captured by the imaging element 1002 in a recording medium such as a hard disk or a semiconductor memory.

The operation unit 1007 issues operation commands for various functions of the imaging element 1000 in response to user operations. The power supply unit 1008 appropriately supplies various powers serving as operation powers of the DSP circuit 1003, the frame memory 1004, the display unit 1005, the recording unit 1006, and the operation unit 1007 to these supply targets.

### <Example of Application to Endoscopic Operation System>

The technology (the present technology) according to the present disclosure can be applied to various products. For example, the technology according to the present disclosure may be applied to an endoscopic operation system.

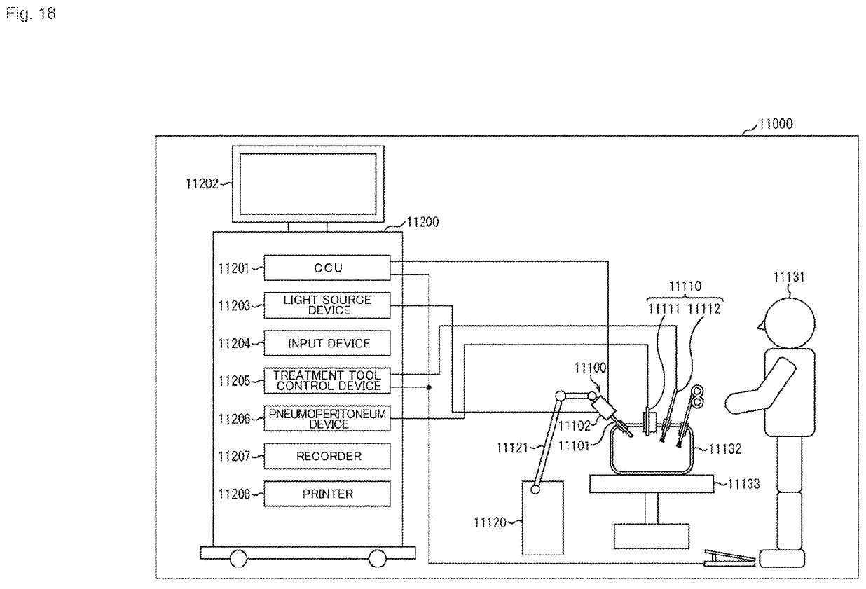

FIG. 18 is a diagram illustrating an example of a schematic configuration of an endoscopic operation system to which the technology according to the present disclosure (the present technology) can be applied.

FIG. 18 shows a state where a surgeon (doctor) 11131 is performing a surgical operation on a patient 11132 on a patient bed 11133 by using the endoscopic operation system 11000. As illustrated, the endoscopic operation system 11000 includes an endoscope 11100, other surgical instruments 11110 such as a pneumoperitoneum tube 11111 and an energized treatment tool 11112, a support arm device 11120 that supports the endoscope 11100, and a cart 11200 equipped with various devices for endoscopic operation.

The endoscope 11100 includes a lens barrel 11101, a region of which having a predetermined length from a distal end is inserted into a body cavity of the patient 11132, and a camera head 11102 connected to a proximal end of the lens barrel 11101. Although the endoscope 11100 configured as a so-called rigid mirror having the rigid lens barrel 11101 is illustrated in the illustrated example, the endoscope 11100 may be configured as a so-called flexible mirror having a flexible lens barrel.

An opening in which an objective lens is fitted is provided at the distal end of the lens barrel 11101. Alight source device 11203 is connected to the endoscope 11100, and light generated by the light source device 11203 is guided to the distal end of the lens barrel by a light guide extending inside the lens barrel 11101 and is radiated toward the observation target in the body cavity of the patient 11132 via the objective lens. The endoscope 11100 may be a direct-viewing endoscope or may be a perspective endoscope or a side-viewing endoscope.

An optical system and an imaging element are provided inside the camera head 11102, and the reflected light (observation light) from the observation target is condensed on the imaging element by the optical system. The observation light is photoelectrically converted by the imaging element, and an electrical signal corresponding to the observation light, that is, an image signal corresponding to an observation image is generated. The image signal is transmitted to a camera control unit (CCU) 11201 as RAW data.

The CCU 11201 is configured by a central processing unit (CPU), a graphics processing unit (GPU), and the like and integrally controls operations of the endoscope 11100 and a display device 11202. Further, the CCU 11201 receives the image signal from the camera head 11102 and performs various kinds of image processing such as development processing (demosaic processing) on the image signal for displaying an image based on the image signal.

The display device 11202 displays an image based on an image signal having been subjected to image processing by the CCU 11201 under the control of the CCU 11201.

The light source device 11203 includes a light source such as a light emitting diode (LED) and supplies the endoscope 11100 with radiation light for imaging an operation site or the like.

The input device 11204 is an input interface for the endoscopic operation system 11000. The user can input various types of information or instructions to the endoscopic operation system 11000 via the input device 11204. For example, the user inputs an instruction to change imaging conditions (a type of radiated light, a magnification, a focal length, or the like) of the endoscope 11100.

A treatment tool control device 11205 controls driving of the energized treatment tool 11112 for cauterizing or incising tissue, sealing a blood vessel, or the like. A pneumoperitoneum device 11206 sends gas into the body cavity through a pneumoperitoneum tube 11111 in order to inflate the body cavity of the patient 11132 for the purpose of securing a visual field for the endoscope 11100 and a working space for the surgeon. A recorder 11207 is a device capable of recording various types of information regarding operation. A printer 11208 is a device that can print various types of information regarding operation in various formats such as text, images, or graphs.

The light source device 11203 that supplies the endoscope 11100 with the radiation light for imaging the operation site can be configured of, for example, an LED, a laser light source, or a white light source configured of a combination thereof. When a white light source is formed by a combination of RGB laser light sources, it is possible to control an output intensity and an output timing of each color (each wavelength) with high accuracy and thus, the light source device 11203 adjusts white balance of the captured image. Further, in this case, laser light from each of the respective RGB laser light sources is radiated to the observation target in a time division manner, and driving of the imaging element of the camera head 11102 is controlled in synchronization with radiation timing such that images corresponding to respective RGB can be captured in a time division manner. According to this method, it is possible to obtain a color image without providing a color filter to the imaging element.

Further, the driving of the light source device 11203 may be controlled to change the intensity of the output light at predetermined time intervals. It is possible to acquire images in a time-division manner by controlling the driving of the imaging element of the camera head 11102 in synchronization with a timing at which the intensity of the light is changed, and it is possible to generate a high dynamic range image without so-called blackout and whiteout by combining the images.

Further, the light source device 11203 may be configured to be able to supply light having a predetermined wavelength band corresponding to special light observation. In the special light observation, for example, so-called narrow band imaging in which a predetermined tissue such as a blood vessel of a mucosal surface layer is imaged with high contrast through radiation of light in a narrower band than irradiation light (that is, white light) at the time of normal observation using a dependence of absorption of light in a body tissue on a wavelength is performed. Alternatively, in the special light observation, fluorescence observation in which an image is obtained using fluorescence generated through excitation light irradiation may be performed. In the fluorescence observation, it is possible to irradiate the body tissue with excitation light and observe the fluorescence from the body tissue (autofluorescence observation), to obtain a fluorescence image by locally injecting a reagent such as indocyanine green (ICG) into the body tissue and irradiating the body tissue with excitation light corresponding to the fluorescence wavelength of the reagent, or the like. The light source device 11203 may be configured to be able to supply the narrow band light and/or the excitation light corresponding to such special light observation.

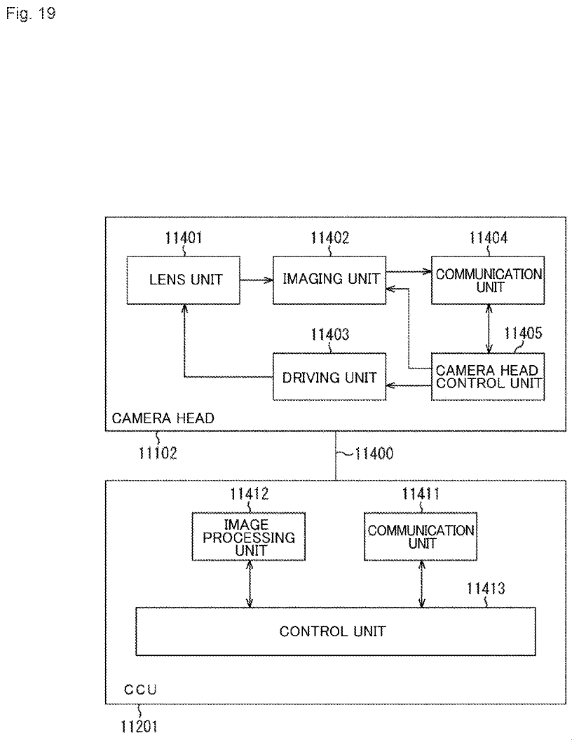

FIG. 19 is a block diagram illustrating an example of a functional configuration of the camera head 11102 and CCU 11201 illustrated in FIG. 18.

The camera head 11102 includes a lens unit 11401, an imaging unit 11402, a driving unit 11403, a communication unit 11404, and a camera head control unit 11405. The CCU 11201 includes a communication unit 11411, an image processing unit 11412, and a control unit 11413. The camera head 11102 and the CCU 11201 are connected to each other such that they can communicate with each other via a transmission cable 11400.

The lens unit 11401 is an optical system provided at a portion for connection to the lens barrel 11101. The observation light taken in from the distal end of the lens barrel 11101 is guided to the camera head 11102 and incident on the lens unit 11401. The lens unit 11401 is configured in combination of a plurality of lenses including a zoom lens and a focus lens.

The number of imaging elements constituting the imaging unit 11402 may be one (so-called single-plate type) or plural (so-called multi-plate type). In a case in which the imaging unit 11402 is configured as a multi-plate type, image signals corresponding to R, G, and B, for example, may be generated by the imaging elements and may be combined to obtain a color image. Alternatively, the imaging unit 11402 may be configured to include a pair of imaging elements for respectively acquiring right-eye image signals and left-eye image signals corresponding to 3D (dimensional) display. By performing the 3D display, the surgeon 11131 can understand a depth of a living tissue in the operation site more accurately. Further, in a case in which the imaging unit 11402 is configured as the multi-plate type, a plurality of lens units 11401 may be provided corresponding to each imaging element.

Further, the imaging unit 11402 may not necessarily be provided in the camera head 11102. For example, the imaging unit 11402 may be provided immediately after the objective lens inside the lens barrel 11101.

The driving unit 11403 includes an actuator, and moves the zoom lens and the focus lens of the lens unit 11401 by a predetermined distance along an optical axis under the control of the camera head control unit 11405. Accordingly, the magnification and focus of the image captured by the imaging unit 11402 can be adjusted appropriately.

The communication unit 11404 is configured of a communication device for transmitting or receiving various information to or from the CCU 11201. The communication unit 11404 transmits an image signal obtained from the imaging unit 11402 to the CCU 11201 through the transmission cable 11400 as RAW data.

In addition, the communication unit 11404 receives a control signal for controlling driving of the camera head 11102 from the CCU 11201 and supplies the control signal to the camera head control unit 11405. The control signal includes, for example, information on the imaging conditions such as information indicating that the frame rate of the captured image is designated, information indicating that the exposure value at the time of imaging is designated, and/or information indicating that the magnification and the focus of the captured image are designated.

The imaging conditions such as the frame rate, the exposure value, the magnification, and the focus described above may be appropriately designated by the user or may be automatically set by the control unit 11413 of the CCU 11201 on the basis of the acquired image signal. In the latter case, a so-called auto exposure (AE) function, an auto focus (AF) function, and an auto white balance (AWB) function are mounted in the endoscope 11100.

The camera head control unit 11405 controls the driving of the camera head 11102 on the basis of the control signal from the CCU 11201 received via the communication unit 11404.

The communication unit 11411 includes a communication device for transmitting/receiving various types of information to/from the camera head 11102. The communication unit 11411 receives an image signal transmitted from the camera head 11102 via the transmission cable 11400.

In addition, the communication unit 11411 transmits a control signal for controlling the driving of the camera head 11102 to the camera head 11102. The image signal or the control signal can be transmitted through electric communication, optical communication, or the like.

The image processing unit 11412 performs various kinds of image processing on the image signal that is the RAW data transmitted from the camera head 11102.

The control unit 11413 performs various kinds of control regarding imaging of an operation site or the like using the endoscope 11100 and a display of a captured image obtained by imaging the operation site or the like. For example, the control unit 11413 generates the control signal for controlling the driving of the camera head 11102.

Further, the control unit 11413 causes the display device 11202 to display the captured image obtained by imaging the operation site or the like on the basis of the image signal having subjected to image processing by the image processing unit 11412. In this case, the control unit 11413 may recognize various objects in the captured image using various image recognition technologies. For example, the control unit 11413 can recognize surgical tools such as forceps, specific biological parts, bleeding, mist when the energized treatment tool 11112 is used and the like by detecting the edge shape and color of the object included in the captured image. When the control unit 11413 causes the display device 11202 to display the captured image, it may cause various types of surgical support information to be superimposed and displayed with the image of the operation site using the recognition result. When the surgical support information is superimposed and displayed, and presented to the surgeon 11131, it is possible to reduce the burden on the surgeon 11131 and the surgeon 11131 can reliably proceed the operation.

The transmission cable 11400 that connects the camera head 11102 to the CCU 11201 is an electrical signal cable compatible with communication of an electrical signal, an optical fiber compatible with optical communication, or a composite cable thereof.

Here, in the illustrated example, wired communication is performed using the transmission cable 11400, but the communication between the camera head 11102 and the CCU 11201 may be performed wirelessly.

### <Example of Application in Moving Body>

The technology according to the present disclosure (the present technology) can be applied in various products. For example, the technology according to the present disclosure may be realized as a device mounted in any type of moving body such as an automobile, an electric automobile, a motorbike, a hybrid electric automobile, a bicycle, a personal mobility, an airplane, a drone, a ship, and a robot.

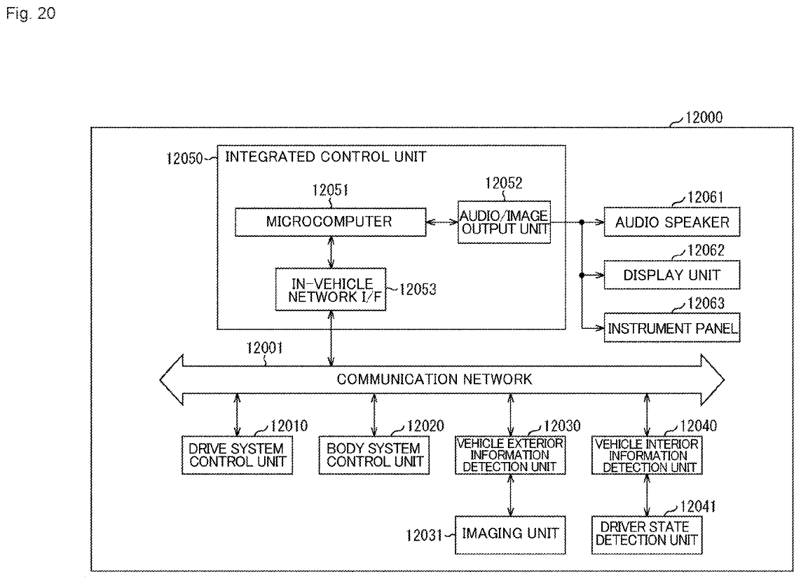

FIG. 20 is a block diagram illustrating a schematic configuration example of a vehicle control system that is an example of a moving body control system to which the technology according to the present disclosure can be applied.

The vehicle control system 12000 includes a plurality of electronic control units connected via a communication network 12001. In the example illustrated in FIG. 20, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, an audio/image output unit 12052, and an in-vehicle network interface (I/F) 12053 are illustrated.

The drive system control unit 12010 controls operations of devices related to a drive system of a vehicle according to various programs. For example, the drive system control unit 12010 functions as a control device for devices such as a driving force generation device for generating a driving force of a vehicle such as an internal combustion engine or a driving motor, a driving force transmission mechanism for transmitting a driving force to wheels, a steering mechanism for adjusting a turning angle of a vehicle, and a braking device that generates a braking force of a vehicle.

The body system control unit 12020 controls operations of various devices mounted in the vehicle body according to various programs. For example, the body system control unit 12020 serves as a control device of a keyless entry system, a smart key system, a power window device, or various lamps such as a head lamp, a back lamp, a brake lamp, a turn signal, and a fog lamp. In this case, radio waves transmitted from a portable device that substitutes for a key or signals of various switches can be input to the body system control unit 12020. The body system control unit 12020 receives inputs of these radio waves or signals and controls a door lock device, a power window device, a lamp, and the like of the vehicle.

The vehicle exterior information detection unit 12030 detects information outside the vehicle in which the vehicle control system 12000 is mounted. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing for peoples, cars, obstacles, signs, and letters on the road based on the received image.

The imaging unit 12031 is an optical sensor that receives light and outputs an electrical signal according to the intensity of the light received. The imaging unit 12031 can output an electrical signal as an image or output it as a distance measurement information. In addition, the light received by the imaging unit 12031 may be visible light or invisible light such as infrared rays.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of the information on the inside and the outside of the vehicle acquired by the vehicle exterior information detection unit 12030 or the vehicle interior information detection unit 12040, and output a control command to the drive system control unit 12010. For example, the microcomputer 12051 can perform coordinated control for the purpose of realizing a function of an advanced driver assistance system (ADAS) including vehicle collision avoidance, shock alleviation, following travel based on an inter-vehicle distance, cruise control, vehicle collision warning, vehicle lane departure warning, or the like.

Further, the microcomputer 12051 can perform coordinated control for the purpose of automated driving or the like in which autonomous travel is performed without depending on operations of the driver by controlling the driving force generation device, the steering mechanism, the braking device, and the like on the basis of information regarding the surroundings of the vehicle acquired by the vehicle exterior information detection unit 12030 or the vehicle interior information detection unit 12040.

In addition, the microcomputer 12051 can output a control command to the body system control unit 12030 based on the information outside the vehicle acquired by the vehicle exterior information detection unit 12030. For example, the microcomputer 12051 can perform coordinated control for antiglare such as switching a high beam to a low beam by controlling a headlamp according to a position of a preceding vehicle or an oncoming vehicle detected by the vehicle exterior information detection unit 12030.

The audio/image output unit 12052 transmits an output signal of at least one of audio and an image to an output device capable of visually or audibly notifying an occupant of a vehicle or the outside of the vehicle of information. In the example illustrated in FIG. 20, an audio speaker 12061, a display unit 12062, and an instrument panel 12063 are illustrated as output devices. The display unit 12062 may include, for example, at least one of an on-board display and a head-up display.

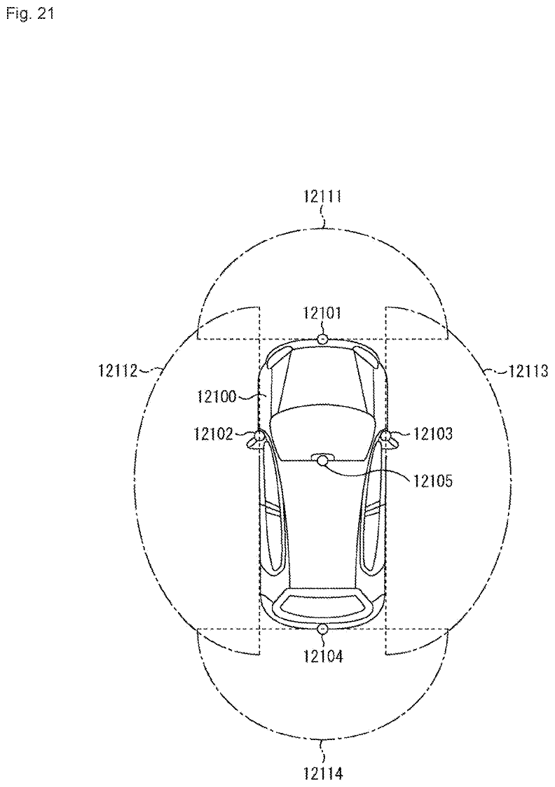

FIG. 21 is a diagram illustrating an example of positions at which the imaging unit 12031 is installed.

In FIG. 21, imaging units 12101, 12102, 12103, 12104, and 12105 are included as the imaging unit 12031.

The imaging units 12101, 12102, 12103, 12104, and 12105 may be provided at positions such as a front nose, side-view mirrors, a rear bumper, and a back door of the vehicle 12100, and an upper part of a windshield inside the vehicle, for example. The imaging unit 12101 provided in the front nose and the imaging unit 12105 provided in the upper portion of the front glass inside the vehicle mainly acquire images on the front side of the vehicle 12100. The imaging units 12102 and 12103 provided in the side-view mirrors mainly acquire images on the lateral sides of the vehicle 12100. The imaging unit 12104 provided in the rear bumper or the backdoor mainly acquires images on the rear side of the vehicle 12100. The imaging unit 12105 included in the upper portion of the front glass inside the vehicle is mainly used to detect preceding vehicles or pedestrians, obstacles, traffic signals, traffic signs, lanes, and the like.

FIG. 21 illustrates an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, a bird's-eye view image of the vehicle 12100 as viewed from above can be obtained by superimposition of image data captured by the imaging units 12101 to 12104.

At least one of the imaging units 12101 to 12104 may have a function for obtaining distance information. For example, at least one of the imaging units 12101 to 12104 may be a stereo camera constituted by a plurality of imaging elements or may be an imaging element having pixels for phase difference detection.

For example, the microcomputer 12051 can extract a three-dimensional object traveling at a predetermined speed (for example, 0 km/h or more) in substantially the same direction as that of the vehicle 12100 which is particularly a closest three-dimensional object on a travel road of the vehicle 12100 as a preceding vehicle by obtaining a distance from each three-dimensional object within the imaging ranges 12111 to 12114 and a temporal change of the distance (a relative speed to the vehicle 12100) based on the distance information obtained from the imaging units 12101 to 12104. Further, the microcomputer 12051 can set an inter-vehicle distance which is guaranteed in advance before a preceding vehicle and perform automated brake control (also including following stop control) or automated acceleration control (also including following start control). In this manner, it is possible to perform coordinated control for the purpose of autonomous driving in which the vehicle autonomously travels without requiring the driver to perform operations.

For example, the microcomputer 12051 can classify and extract three-dimensional object data regarding three-dimensional objects into two-wheeled vehicles, ordinary vehicles, large vehicles, pedestrians, and other three-dimensional objects such as utility poles on the basis of distance information obtained from the imaging units 12101 to 12104 and use the three-dimensional object data for automatic avoidance of obstacles. For example, the microcomputer 12051 identifies obstacles in the vicinity of the vehicle 12100 into obstacles that can be visually recognized by the driver of the vehicle 12100 and obstacles that are difficult to visually recognize. Then, the microcomputer 12051 can determine a risk of collision indicating the degree of risk of collision with each obstacle, and can perform driving assistance for collision avoidance by outputting a warning to a driver through the audio speaker 12061 or the display unit 12062 and performing forced deceleration or avoidance steering through the drive system control unit 12010 when the risk of collision has a value equal to or greater than a set value and there is a possibility of collision.

At least one of the imaging units 12101 to 12104 may be an infrared camera that detects infrared light. For example, the microcomputer 12051 can recognize a pedestrian by determining whether or not a pedestrian is present in images captured by the imaging units 12101 to 12104. Such recognition of a pedestrian is performed by, for example, a procedure of extracting a feature point in captured images of the imaging units 12101 to 12104 serving as infrared cameras, and a procedure of performing pattern matching processing on a series of feature points indicating the contour of an object to determine whether or not the object is a pedestrian. When the microcomputer 12051 determines that a pedestrian is present in the captured images of the imaging units 12101 to 12104 and recognizes the pedestrian, the audio/image output unit 12052 controls the display unit 12062 such that a square contour line for emphasis is superimposed on the recognized pedestrian and is displayed. In addition, the audio/image output unit 12052 may control the display unit 12062 so that an icon or the like indicating a pedestrian is displayed at a desired position.

In addition, the system as used herein refers to an entire device configured by a plurality of devices.

The advantageous effects described in the present specification are merely exemplary and are not intended as limiting, and other advantageous effects may be obtained.

Embodiments of the present technology are not limited to the above-described embodiments and can be modified in various forms within the scope of the present technology departing from the gist of the present technology.

Meanwhile, the present technology can also take the following configurations.

(1)

An imaging element including laminated first and second photoelectric conversion parts provided between a first surface of a semiconductor substrate and a second surface opposite to the first surface,

wherein an impurity profile of the first photoelectric conversion part is a profile having a peak on the first surface side, and

an impurity profile of the second photoelectric conversion part is a profile having a peak on the second surface side.

(2)

The imaging element according to (1), wherein a side on which an impurity concentration of the first photoelectric conversion part is low and a side on which an impurity concentration of the second photoelectric conversion part is low face each other.

(3)

The imaging element according to (1) or (2), further including a third photoelectric conversion part including an organic photoelectric conversion film laminated on the first surface side and sandwiched between a lower electrode and an upper electrode.

(4)

The imaging element according to (1) or (2), further including a third photoelectric conversion part in the semiconductor substrate.

(5)

The imaging element according to any one of (1) to (4), wherein the first surface side of the first photoelectric conversion part is formed in an uneven shape.

(6)

A manufacturing method of a manufacturing apparatus for manufacturing an imaging element, the manufacturing method including

laminated first and second photoelectric conversion parts provided between a first surface of a semiconductor substrate and a second surface opposite to the first surface,

the manufacturing method including manufacturing an imaging element in which an impurity profile of the first photoelectric conversion part is a profile having a peak on the first surface side, and

an impurity profile of the second photoelectric conversion part is a profile having a peak on the second surface side.

(7)

The manufacturing method according to (6), further including forming the first photoelectric conversion part by ion implantation from the first surface side, and forming the second photoelectric conversion part by ion implantation from the second surface side.

(8)

The manufacturing method according to (7), further including forming a third photoelectric conversion part including an organic photoelectric conversion film sandwiched between a lower electrode and an upper electrode on the first surface side.

(9)

The manufacturing method according to (7), further including forming a third photoelectric conversion part by ion implantation from the first surface side.

(10)

The manufacturing method according to any one of (6) to (9), wherein unevenness is formed on the first surface before the first photoelectric conversion part is formed.

(11)

The manufacturing method according to any one of (6) to (10), wherein the semiconductor substrate is a silicon on insulator (SOI) substrate.

(12)

An electronic apparatus including an imaging element including laminated first and second photoelectric conversion parts provided between a first surface of a semiconductor substrate and a second surface opposite to the first surface,

wherein an impurity profile of the first photoelectric conversion part is a profile having a peak on the first surface side, and

an impurity profile of the second photoelectric conversion part is a profile having a peak on the second surface side; and

a processing unit that processes a signal from the imaging element.

### REFERENCE SIGNS LIST

1 Imaging element
2 Pixel
3 Pixel area
4 Vertical drive circuit
5 Column signal processing circuit
6 Horizontal drive circuit
7 Output circuit
8 Control circuit
9 Vertical signal line
10 Horizontal signal line
11 Substrate
12 Process
15 Photoelectric conversion region
16 Well region
17 Semiconductor substrate
18 p-type semiconductor region
19 n-type semiconductor region
20 p-type semiconductor region
21 n-type semiconductor region
22 p-type semiconductor region
23 Gate electrode
27 Multilayer wiring layer
28 Wiring
29 Interlayer insulating film
32 Through-electrode
33 Insulating film
34a Upper electrode
34b Lower electrode
35 Insulating film
36a Organic photoelectric conversion film
36b Passivation film
40 Gate electrode
41 Gate electrode
42 Gate electrode
43 Drain region
44 Drain region
45 Drain region
46 Drain region
51 Planarization film
52 On-chip lens
61 Support substrate
101 Support substrate
131 Silicon layer
201 SOI substrate
202 BOX layer
301 p-type semiconductor region
302 n-type semiconductor region
303 p-type semiconductor region
304 n-type semiconductor region
305 p-type semiconductor region
306 n-type semiconductor region
307 p-type semiconductor region
308, 309 Gate electrode
351 Support substrate
401 p-type semiconductor region
402 n-type semiconductor region
403 p-type semiconductor region

1. An imaging element comprising laminated first and second photoelectric conversion parts provided between a first surface of a semiconductor substrate and a second surface opposite to the first surface,
wherein an impurity profile of the first photoelectric conversion part is a profile having a peak on the first surface side, and
an impurity profile of the second photoelectric conversion part is a profile having a peak on the second surface side.

2. The imaging element according to claim 1, wherein a side on which an impurity concentration of the first photoelectric conversion part is low and a side on which an impurity concentration of the second photoelectric conversion part is low face each other.

3. The imaging element according to claim 1, further including a third photoelectric conversion part including an organic photoelectric conversion film laminated on the first surface side and sandwiched between a lower electrode and an upper electrode.

4. The imaging element according to claim 1, further including a third photoelectric conversion part in the semiconductor substrate.

5. The imaging element according to claim 1, wherein the first surface side of the first photoelectric conversion part is formed in an uneven shape.

6. A manufacturing method of a manufacturing apparatus for manufacturing an imaging element, the manufacturing method comprising
manufacturing an imaging element including laminated first and second photoelectric conversion parts provided between a first surface of a semiconductor substrate and a second surface opposite to the first surface,
wherein an impurity profile of the first photoelectric conversion part is a profile having a peak on the first surface side, and
an impurity profile of the second photoelectric conversion part is a profile having a peak on the second surface side.

7. The manufacturing method according to claim 6, further comprising forming the first photoelectric conversion part by ion implantation from the first surface side; and
forming the second photoelectric conversion part by ion implantation from the second surface side.

8. The manufacturing method according to claim 7, further comprising forming a third photoelectric conversion part including an organic photoelectric conversion film sandwiched between a lower electrode and an upper electrode on the first surface side.

9. The manufacturing method according to claim 7, further comprising forming a third photoelectric conversion part by ion implantation from the first surface side.

10. The manufacturing method according to claim 6, wherein unevenness is formed on the first surface before the first photoelectric conversion part is formed.

11. The manufacturing method according to claim 6, wherein the semiconductor substrate is a silicon on insulator (SOI) substrate.

12. An electronic apparatus comprising: an imaging element including laminated first and second photoelectric conversion parts provided between a first surface of a semiconductor substrate and a second surface opposite to the first surface,
wherein an impurity profile of the first photoelectric conversion part is a profile having a peak on the first surface side, and
an impurity profile of the second photoelectric conversion part is a profile having a peak on the second surface side; and
a processing unit that processes a signal from the imaging element.
